(19) United States
(12) Patent Application Publication
(10) Pub. No.: US 2021/0008684 A1
(43) Pub. Date: Jan. 14, 2021

(54) SUBSTRATE PROCESSING APPARATUS AND STORAGE MEDIUM

(71) Applicant: EBARA CORPORATION, Tokyo (JP)

(72) Inventors: Kunimasa Matsushita, Tokyo (JP); Shuichi Kamata, Tokyo (JP); Hiroshi Ishikawa, Tokyo (JP)

(21) Appl. No.: 16/922,171

(22) Filed: Jul. 7, 2020

(30) Foreign Application Priority Data
Jul. 12, 2019 (JP) 2019-129858
Oct. 31, 2019 (JP) 2019-198106

(51) Int. Cl. B24B 37/005; B24B 37/20

(52) U.S. Cl. CPC B24B 37/005; B24B 37/20

(57) ABSTRACT

A substrate processing system capable of reliably releasing a wafer without damaging the wafer is disclosed. The substrate processing system 200 includes a top ring 31, a vacuum forming mechanism 220, and a controller 5. A program causes a processer 5b to measure a height of the top ring 31, to compare the height of the top ring 31 with a suction start position, and to form a vacuum inside an elastic bag 46 based on a result of comparison between the height of the top ring 31 and the suction start position.

### CROSS REFERENCE TO RELATED APPLICATION

This document claims priorities to Japanese Patent Application Number 2019-129858 filed Jul. 12, 2019 and Japanese Patent Application Number 2019-198106 filed Oct. 31, 2019, the entire contents of which are hereby incorporated by reference.

### BACKGROUND

There is a substrate processing apparatus having a configuration for passing a wafer between a transfer stage and a top ring (e.g., see Japanese laid-open patent publication No. 2012-129559). In such substrate processing apparatus, a retainer ring surrounding a periphery of the wafer is elevated relative to the wafer when the wafer is passed on.

However, if the retainer ring rises while an inside of an elastic bag placed between a top ring body and the retainer ring is open to the atmosphere, there is a risk that the retainer ring will not rise normally due to the air remaining inside the elastic bag. When the wafer is released in this state, the wafer may come into contact with the retainer ring and the wafer may be damaged.

### SUMMARY OF THE INVENTION

According to an embodiment, there is provided a substrate processing system and a non-transitory computer-readable storage medium capable of reliably releasing a wafer without damaging the wafer.

If the retainer ring is not securely attached to the top ring body, the retainer ring may not rise normally. When the wafer is released in this state, the wafer may come into contact with the retainer ring and the wafer may be damaged.

According to an embodiment, there is provided a substrate processing system and a non-transitory computer-readable storage medium capable of determining whether the retainer ring is securely attached to the top ring body.

Embodiments, which will be described below, relates to a substrate processing system and a non-transitory computer-readable storage medium that stores a program for operating components of the substrate processing system.

In an embodiment, there is provided a substrate processing system comprising: a top ring comprising a vertically movable retainer ring and an elastic bag configured to vertically move the retainer ring; a vacuum forming mechanism coupled to the elastic bag; and a controller connected to the vacuum forming mechanism, wherein the controller comprises a memory storing a program and a processer executing operations according to the program, and wherein the program causes the processer to measure a height of the top ring lowering to a top-ring lowered position, the processer to compare the height of the top ring with a suction start position, and the vacuum forming mechanism to form a vacuum inside the elastic bag based on a result of comparing the height of the top ring with the suction start position.

In an embodiment, the program causes the vacuum forming mechanism to form the vacuum inside the elastic bag on a condition that the height of the top ring is lower than the suction start position.

In an embodiment, the program causes the processer to measure a temporal change in the height of the retainer ring until the top ring reaches the top-ring lowered position, the processer to compare whether or not an amount of overshoot of the temporal change is within a predetermined allowable range, and the processer to change the suction start position to a position higher than the top-ring lowered position on a condition that the amount of overshoot is not within the predetermined allowable range.

In an embodiment, the program causes the processer to repeat an operation of changing the suction start position to a position higher than the top-ring lowered position until the amount of overshoot is within the allowable range.

In an embodiment, the program causes the processer to change the suction start position based on a distance between a most lowered position and a most elevated position of the retainer ring.

In an embodiment, the program causes the processer to measure a wear amount of the retainer ring, and the processer to reflect a distance corresponding to the wear amount of the retainer ring to the suction start position.

In an embodiment, the program causes the processer to measure the height of the retainer ring after the top ring is lowered to the top-ring lowered position, the processer to judge whether or not the height of the measured retainer ring is higher than the height of a previously measured retainer ring, and the processer to determine a start of a retry operation to lower the top ring again on a condition that the height of the measured retainer ring is higher than the height of the previously measured retainer ring.

In an embodiment, there is provided a non-transitory computer-readable storage medium storing a program, the program for causing a computer to perform steps comprising: lowering a top ring to a top-ring lowered position by a top-ring vertically moving device, the top ring comprising a vertically movable retainer ring and an elastic bag configured to vertically move the retainer ring; measuring a height of the top ring lowering; comparing the height of the top ring with a suction start position; and forming a vacuum inside the elastic bag by a vacuum forming mechanism coupled to the elastic bag based on a result of comparing the height of the top ring with the suction start position.

In an embodiment, forming the vacuum inside the elastic bag by the vacuum forming mechanism on a condition that the height of the top ring is lower than the suction start position.

In an embodiment, measuring a temporal change of the height of the retainer ring until the top ring reaches to the top-ring lowered position; comparing whether or not an amount of overshoot of the temporal change is within a predetermined allowable range; and changing the suction start position to a position higher than the top-ring lowered position on a condition that the amount of overshoot is not within the predetermined allowable range.

In an embodiment, repeating an operation of changing the suction start position to a position higher than the top-ring lowered position until the amount of overshoot is within the allowable range.

In an embodiment, changing the suction start position based on a distance between a most lowered position and a most elevated position of the retainer ring.

In an embodiment, measuring a wear amount of the retainer ring; and reflecting a distance corresponding to the wear amount of the retainer ring to the suction start position.

In an embodiment, measuring the height of the retainer ring after the top ring is lowered to the top-ring lowered position; judging whether or not the height of the measured retainer ring is higher than the height of a previously measured retainer ring; and determining a start of a retry operation to lower the top ring again on a condition that the height of the measured retainer ring is higher than the height of the previously measured retainer ring.

In an embodiment, there is provided a substrate processing system comprising: a top ring comprising a retainer ring and a top ring body attached to the retainer ring; a measuring device configured to directly or indirectly measure a height distribution of the retainer ring; and a controller comprising a memory storing a program and a processer executing operations according to the program, the controller being connected to the measuring device, wherein the program causes the processer to compare a height distribution of the retainer ring with a predetermined judgement standard, and the processer to judge an attachment error of the retainer ring to the top ring body based on a result of comparison between the height distribution of the retainer ring and the judgment standard.

In an embodiment, the judgement standard comprises an allowable upper limit value indicating an allowable upper limit of the height of the retainer ring, and wherein the program causes the processer to compare a maximum value obtained from the height distribution of the retainer ring with the allowable upper limit value, and the processer to judge the attachment error of the retainer ring to the top ring body on a condition that the maximum value is larger than the allowable upper limit value.

In an embodiment, the judgement standard comprises an allowable lower limit value indicating an allowable lower limit of the height of the retainer ring, and wherein the program causes the processer to compare a minimum value obtained from the height distribution of the retainer ring with the allowable lower limit value, and the processer to judge the attachment error of the retainer ring to the top ring body on a condition that the minimum value is smaller than the allowable lower limit value.

In an embodiment, the judgement standard comprises an allowable difference value between an allowable upper limit and an allowable lower limit of the retainer ring, and wherein the program causes the processer to compare a difference value between a maximum value and a minimum value obtained a height distribution of the retainer ring, and the processer to judge the attachment error of the retainer ring to the top ring body on a condition that the difference value is larger than the allowable difference limit value.

In an embodiment, the measuring device comprises a height measurement sensor configured to detect a vertical direction movement of the retainer ring, and wherein the controller causes the processer to obtain a height distribution of the retainer ring based on height data in a plurality of rotational angle positions of the retainer ring detected by the height measurement sensor.

In an embodiment, the measuring device comprises a pressure measurement sensor configured to detect a pressure of the retainer ring moving vertically, wherein the controller causes the processer to obtain a pressure distribution of the retainer ring corresponding to the height distribution of the retainer ring based on pressure data in a plurality of rotational angle positions of the retainer ring detected by the pressure measurement sensor.

In an embodiment, the memory stores a model constructed by a machine learning algorithm, and wherein the processer inputs at least a polishing condition of a substrate and a type of retainer ring to be used into the model, and executes operations to output the judgement standard from the model.

In an embodiment, the model is constructed based on a data set comprising a combination of actual judgement standard, a successful rate of substrate release based on actual judgement standard, and a throughput of a substrate processing apparatus.

In an embodiment, there is provided a non-transitory computer-readable storage medium storing a program, the program for causing a computer to perform steps comprising: comparing a height distribution of a retainer ring attached to a top ring body and a predetermined judgement standard; and judging an attachment error of the retainer ring to the top ring body based on a result of comparison between the height distribution of the retainer ring and the judgment standard.

In an embodiment, comparing a maximum value obtained by the height distribution of the retainer ring and an allowable upper limit value indicating an allowable upper limit of the height of the retainer ring; and judging the attachment error of the retainer ring to the top ring body on a condition that the maximum value is larger than the allowable upper limit value.

In an embodiment, comparing a minimum value obtained from the height of the retainer ring and an allowable lower limit value indicating an allowable lower limit of the height of the retainer ring; and judging the attachment error of the retainer ring to the top ring body on a condition that the minimum value is smaller than the allowable lower limit value.

In an embodiment, comparing a difference value between a maximum value and a minimum value obtained from the height distribution of the retainer ring with an allowable difference value between an allowable upper limit and an allowable lower limit of the height of the retainer ring; and judging the attachment error of the retainer ring to the top ring body on a condition that the difference value is larger than the allowable difference value.

The controller operates the vacuum forming mechanism to form a vacuum inside the elastic bag. Thus, the substrate processing system can reliably elevate the retainer ring until the lower surface of the retainer ring is positioned higher than the upper surface of the wafer. As a result, the substrate processing system is able to reliably release the wafer.

The controller can determine to judge the abnormality in the attachment of the retainer ring to the top ring body by comparing the height distribution of the retainer ring with a predetermined judgment standard. Thus, the substrate processing system can determine whether the retainer ring is securely attached to the top ring body.

### BRIEF DESCRIPTION OF THE DRAWINGS

FIG. 1 is a plan view showing one embodiment of a substrate processing apparatus;

FIG. 2 is a cross-sectional view schematically showing atop ring;

FIG. 3A is a side view showing a positional relationship between a retainer-ring station and a top ring, and FIG. 3B is a plan view showing a positional relationship between the retainer ring station and a transfer stage;

FIG. 4A is a cross-sectional view showing a push-up mechanism, and FIG. 4B is a cross-sectional view showing the push-up mechanism when contacting the retainer ring;

FIG. 5 is a view showing a substrate processing system;

FIG. 6 is a flowchart showing one embodiment of an operation of a controller;

FIGS. 7A through 7D are views for explaining the operation of components of the substrate processing system;

FIG. 8 is a view showing a distance sensor for detecting a height of the top ring;

FIG. 9 is a perspective view showing the retainer-ring station including a height measurement sensor;

FIG. 10 is a graph showing a temporal change in the height of the retainer ring;

FIG. 11 is a flowchart showing another embodiment of the operation of the controller;

FIG. 12 is a view showing a most lowered position and a most elevated position of the retainer ring;

FIG. 13 is a flowchart showing a further embodiment of the operation of the controller;

FIG. 14 is a cross-sectional view schematically showing the top ring;

FIG. 15A is a cross-sectional view showing the push-up mechanism, and FIG. 15B is a cross-sectional view showing the push-up mechanism when in contact with the retainer ring;

FIG. 16 is a view showing the substrate processing system;

FIG. 17 is a view showing the plurality of rotational angle positions of the retainer ring;

FIG. 18 is a view showing a flowchart for measuring a height of the retainer ring at a plurality of rotational angle positions of the retainer ring;

FIG. 19 is a view showing a measuring device with a plurality of height measurement sensors;

FIG. 20 is a view a flowchart for judging the attachment error of the retainer ring to the top ring body;

FIG. 21 is a view a flowchart for judging the attachment error of the retainer ring to the top ring body;

FIG. 22 is a view a flowchart for judging the attachment error of the retainer ring to the top ring body;

FIG. 23 is a view showing another embodiment of the measuring device;

FIG. 24 is a view showing the measuring device with a plurality of pressure measuring sensors; and

FIG. 25 is a view to illustrate how to construct a learned model.

### DESCRIPTION OF THE EMBODIMENTS

A substrate processing apparatus according to embodiments will be described in detail with reference to drawings. Identical or corresponding parts are denoted by identical reference numerals, and will not be described in duplication.

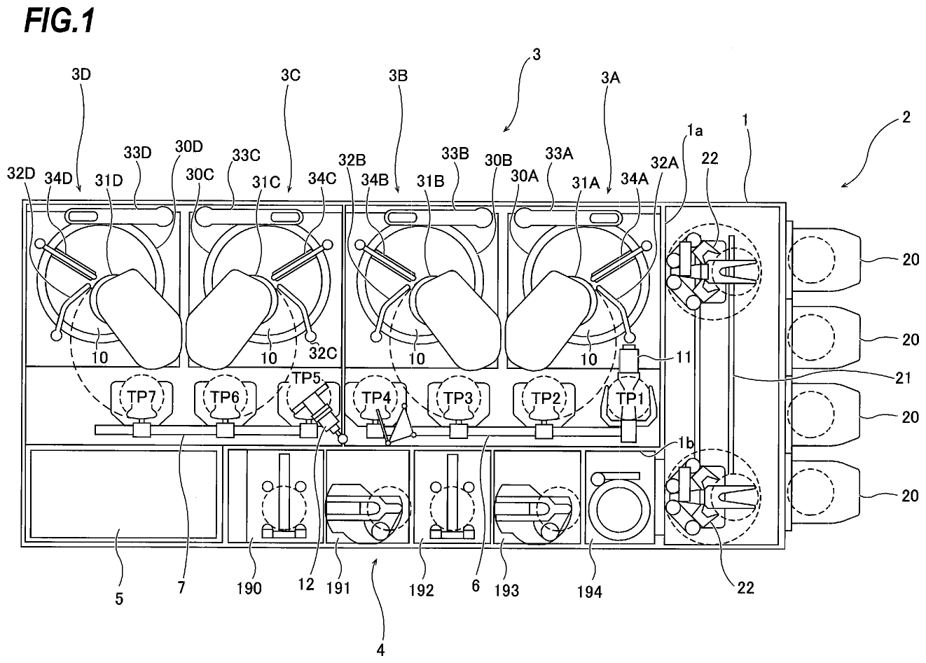

FIG. 1 is a plan view showing one embodiment of a substrate processing apparatus. As shown in FIG. 1, the substrate processing apparatus includes a housing 1 in substantially a rectangular form. An interior of the housing 1 is divided by partition walls 1a and 1b into a loading-and-unloading section 2, a polishing section 3, and a cleaning section 4. The loading-and-unloading section 2, the polishing section 3, and the cleaning section 4 are assembled independently of each other, and air is discharged from these sections independently. The substrate processing apparatus further includes a controller 5 for controlling substrate processing operations.

The loading-and-unloading section 2 includes two or more (four in this embodiment) front loading units 20 on which wafer cassettes, each storing plural wafers (substrates), are placed. The front loading units 20 are arranged adjacent to the housing 1 along a width direction of the substrate processing apparatus (a direction perpendicular to a longitudinal direction of the substrate processing apparatus). Each of the front loading units 20 is capable of receiving thereon an open cassette, an SMIF (Standard Manufacturing Interface) pod, or a FOUP (Front Opening Unified Pod). The SMIF and FOUP are a hermetically sealed container which can house a wafer cassette therein and is covered with a partition wall to thereby provide interior environments isolated from an external space.

The loading-and-unloading section 2 includes a moving mechanism 21 extending along an arrangement direction of the front loading units 20. A transfer robot (or a loader) 22 is installed on the moving mechanism 21 and is movable along the arrangement direction of the wafer cassettes. The transfer robot 22 is configured to move on the moving mechanism 21 so as to access the wafer cassettes mounted on the front loading units 20. The transfer robot 22 has vertically arranged two hands, which are separately used. The upper hand can be used for returning a processed wafer to the wafer cassette, and the lower hand can be used for taking out a wafer, to be processed, from the wafer cassette. The lower hand of the transfer robot 22 is configured to be able to rotate about its own axis, so that the wafer can be reversed.

The loading-and-unloading section 2 is required to be a cleanest area. Therefore, pressure in the interior of the loading-and-unloading section 2 is kept higher at all times than pressures in the exterior space of the substrate processing apparatus, the polishing section 3, and the cleaning section 4. The polishing section 3 is the dirtiest area, because slurry is used as a polishing liquid. Therefore, negative pressure is produced in the polishing section 3, and the pressure in polishing section 3 is kept lower than the internal pressure of the cleaning section 4. A filter fan unit (not shown) having a clean air filter, such as HEPA filter, ULPA filter or a chemical filter, is provided in the loading-and-unloading section 2. This filter fan unit removes particles, toxic vapor, and toxic gas from air to form flow of clean air at all times.

The polishing section 3 is an area where a surface of a wafer is polished (or planarized). This polishing section 3 includes a first polishing unit 3A, a second polishing unit 3B, a third polishing unit 3C, and a fourth polishing unit 3D. The first polishing unit 3A, the second polishing unit 3B, the third polishing unit 3C, and the fourth polishing unit 3D are arranged along the longitudinal direction of the substrate processing apparatus as shown in FIG. 1.

As shown in FIG. 1, the first polishing unit 3A includes a polishing table 30A to which a polishing pad 10 having a polishing surface is attached, a top ring 31A for holding a wafer and pressing the wafer against the polishing pad 10 on the polishing table 30A to polish the wafer, a polishing liquid supply nozzle 32A for supplying a polishing liquid and a dressing liquid (e.g., pure water) onto the polishing pad 10, a dresser 33A for dressing the polishing surface of the polishing pad 10, and an atomizer 34A for ejecting a mixture of a liquid (e.g., pure water) and a gas (e.g., nitrogen gas) or a liquid (e.g., pure water) in an atomized state onto the polishing surface of the polishing pad 10.

Similarly, the second polishing unit 3B includes a polishing table 30B to which a polishing pad 10 is attached, a top ring 31B, a polishing liquid supply nozzle 32B, a dresser 33B, and an atomizer 34B. The third polishing unit 3C includes a polishing table 30C to which a polishing pad 10 is attached, a top ring 31C, a polishing liquid supply nozzle 32C, a dresser 33C, and an atomizer 34C. The fourth polishing unit 3D includes a polishing table 30D to which a polishing pad 10 is attached, a top ring 31D, a polishing liquid supply nozzle 32D, a dresser 33D, and an atomizer 34D.

A transport mechanism for transporting wafers is described. As shown in FIG. 1, a first linear transporter 6 is disposed adjacent to the first polishing unit 3A and the second polishing unit 3B. The first linear transporter 6 is a mechanism for transporting a wafer between four transport positions, i.e., a first transport position TP1, a second transport position TP2, a third transport position TP3, and a fourth transport position TP4 spaced successively from the loading/unloading section 2, arrayed along the direction in which the first polishing unit 3A and the second polishing unit 3B are arrayed.

A second linear transporter 7 is disposed adjacent to the third polishing unit 3C and the fourth polishing unit 3D. The second linear transporter 7 is a mechanism for transporting a wafer between three transport positions, i.e., a fifth transport position TP5, a sixth transport position TP6, and a seventh transport position TP7 spaced successively from the loading/unloading section 2, arrayed along the direction in which the third polishing unit 3C and the fourth polishing unit 3D are arrayed.

A wafer is transported to the first polishing unit 3A and the second polishing unit 3B by the first linear transporter 6. As described above, the top ring 31A of the first polishing unit 3A is movable between a polishing position and the second transport position TP2. Therefore, the transfer of the wafer to the top ring 31A is performed at the second transport position TP2. Similarly, the top ring 31B of the second polishing unit 3B is movable between a polishing position and the third transport position TP3. The transfer of the wafer to the top ring 31B is performed at the third transport position TP3. The top ring 31C of the third polishing unit 3C is movable between a polishing position and the sixth transport position TP6. The transfer of the wafer to the top ring 31C is performed at the sixth transport position TP6. The top ring 31D of the fourth polishing unit 3D is movable between a polishing position and the seventh transport position TP7. The transfer of the wafer to the top ring 31D is performed at the seventh transport position TP7.

A lifter 11 for receiving the wafer from the transport robot 22 is disposed in the first transport position TP1. The wafer is transferred from the transport robot 22 to the first linear transporter 6 by the lifter 11. The partition 1a has a shutter (not shown) positioned therein between the lifter 11 and the transport robot 22. When the wafer is to be transferred, the shutter is opened to allow the transport robot 22 to transfer the wafer to the lifter 11. A swing transporter 12 is disposed between the first linear transporter 6, the second linear transporter 7, and the cleaning section 4. The swing transporter 12 has a hand movable between the fourth transport position TP4 and the fifth transport position TP5. The transfer of the wafer from the first linear transporter 6 to the second linear transporter 7 is performed by the swing transporter 12. The wafer is transported by the second linear transporter 7 to the third polishing unit 3C and/or the fourth polishing unit 3D. Further, the wafer that has been polished in the polishing section 3 is transported to the cleaning section 4 by the swing transporter 12. The cleaning section 4 is divided into a first cleaning chamber 190, a first transport chamber 191, a second cleaning chamber 192, a second transport chamber 193, and a drying chamber 194.

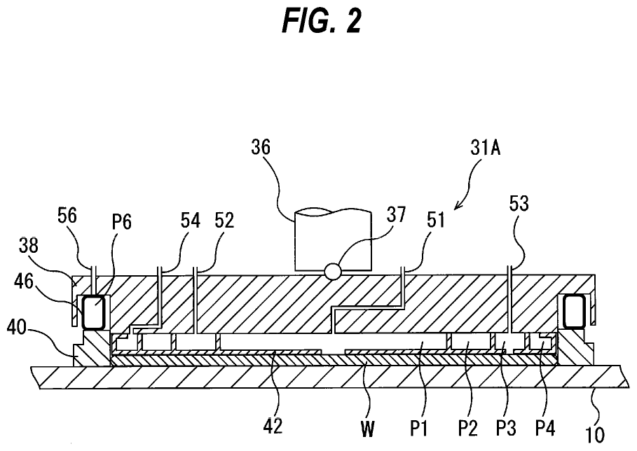

FIG. 2 is a cross-sectional view schematically showing the top ring 31A. The top ring 31A is coupled to a lower end of a top ring shaft 36 via a universal joint 37. This universal joint 37 is a ball joint configured to transmit rotation of the top ring shaft 36 to the top ring 31A while allowing the top ring 31A and the top ring shaft 36 to tile with respect to each other. The top ring 31A has a top ring body 38 in substantially a disk shape and a retainer ring 40 provided on a lower portion of the top ring body 38. The top ring body 38 is made of a material having high strength and rigidity, such as metal or ceramic. The retainer ring 40 is made of highly rigid resin, ceramic, or the like. The retainer ring 40 may be integrally formed with the top ring body 38.

A circular elastic pad 42 which contacts the wafer W is accommodated in a space formed inside the top ring body 38 and the retainer ring 40. The elastic pad 42 is attached to a lower surface of the top ring body 38. Four pressure chambers (air bags) P1, P2, P3, and P4 are provided to the elastic pad 42. A pressurized fluid (e.g., a pressurized air) is supplied into the pressure chambers P1, P2, P3, and P4 or a vacuum is developed in the pressure chambers P1, P2, P3, and P4 via fluid passages 51, 52, 53, and 54, respectively. The central pressure chamber P1 has a circular shape, and the other pressure chambers P2, P3, and P4 have an annular shape. These pressure chambers P1, P2, P3, and P4 are in a concentric arrangement.

Internal pressures of the pressure chambers P1, P2, P3, and P4 can be changed independently by a pressure adjuster (not shown) to independently adjust pressing forces applied to four zones: a central zone, an inner intermediate zone, an outer intermediate zone, and a peripheral zone. The retainer ring 40 can be pressed against the polishing pad 10 with a predetermined pressure by raising and lowering the entire top ring 31A.

A retainer ring 40 is arranged around the periphery of the wafer W so as to prevent the wafer W from coming off the top ring 31A during polishing of the wafer W. An opening (not shown) is formed in a portion of the elastic pad 42 which forms the pressure chamber P3. When a vacuum is developed in the pressure chamber P3, the wafer W is held by the top ring 31A via vacuum suction. On the other hand, the substrate W is released from the top ring 31A by supplying a nitrogen gas, dry air, pressurized air, or the like into the pressure chamber P3.

An elastic bag 46 is provided between the retainer ring 40 and the top ring body 38, and a pressure chamber P6 is formed in the elastic bag 46. The retainer ring 40 is movable in the vertical direction relative to the top ring body 38. A fluid passage 56 in fluid communication with the pressure chamber P6 is provided, so that the pressurized fluid (e.g., the pressurized air) is supplied into the pressure chamber P6 through the fluid passage 56. Internal pressure of the pressure chamber P6 is adjustable via the pressure adjuster. Therefore, the pressing force of the retainer ring 40 against the polishing pad 10 can be adjusted independently of the pressing force applied to the substrate W.

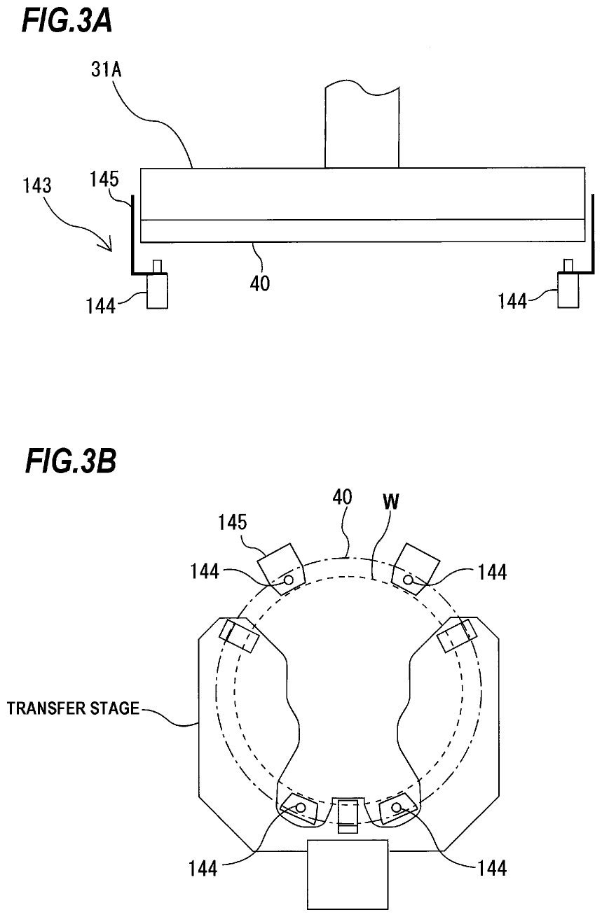

FIG. 3A is a side view showing a positional relationship between a retainer-ring station and the top ring, and FIG. 3B is a plan view showing a positional relationship between the retainer-ring station and a transfer stage. The retainer-ring station provided at the second transfer position TP2 will be described below.

The retainer-ring station 143 includes plural push-up mechanisms 144 configured to push the retainer ring 40 of the top ring 31A upward, and a support base 145 supporting these push-up mechanisms 144. The push-up mechanisms 144 are located at a vertical position between the top ring 31A and the transfer stage of the first linear transporter 6. As shown in FIG. 3B, the push-up mechanisms 144 and the transfer stage are arranged so as not to contact each other.

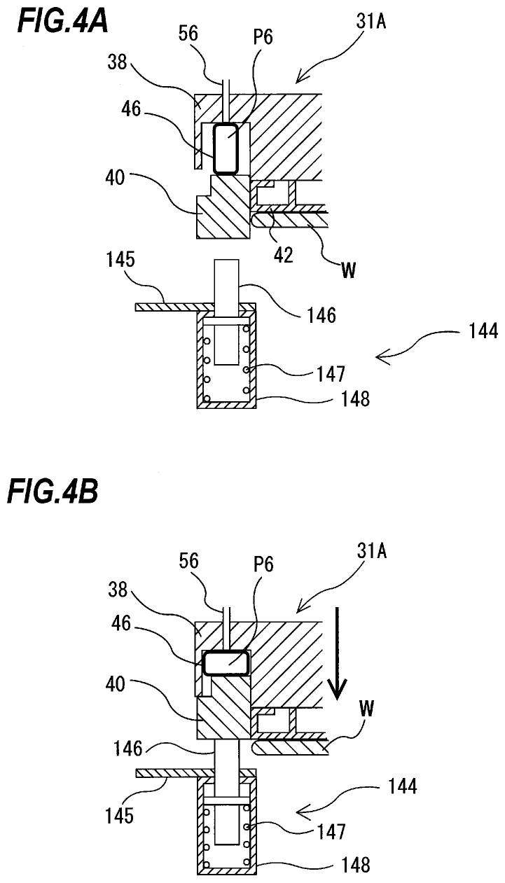

FIG. 4A is a cross-sectional view showing a push-up mechanism 144, and FIG. 4B is a cross-sectional view showing the push-up mechanism 144 when contacting the retainer ring. The push-up mechanism 144 includes a push-up pin 146 arranged to contact the retainer ring 40, a spring 147 as a biasing mechanism configured to push the push-up pin 146 upward, and a casing 148 configured to house the push-up pin 146 and the spring 147 therein. The push-up mechanism 144 is located such that the push-up pin 146 faces a lower surface of the retainer ring 40. When the top ring 31A is lowered, the lower surface of the retainer ring 40 is brought into contact with the push-up pins 146. As shown in FIG. 4B, the retainer ring 40 is pushed upward by the push-up pins 146 to a position above the wafer W.

As described above, when the retainer ring 40 is pushed up by the push-up pin 146 with the inside of the elastic bag 46 open to the atmosphere, the retainer ring 40 may not move completely to a position above the wafer W due to the air remaining inside the elastic bag 46. When the wafer W is released in this state, the wafer W may contact the retainer ring 40 and the wafer W may be damaged.

Therefore, the substrate processing system capable of reliably releasing the wafer W without damaging the wafer W is provided. Details of the substrate processing system are described below with reference to the drawings.

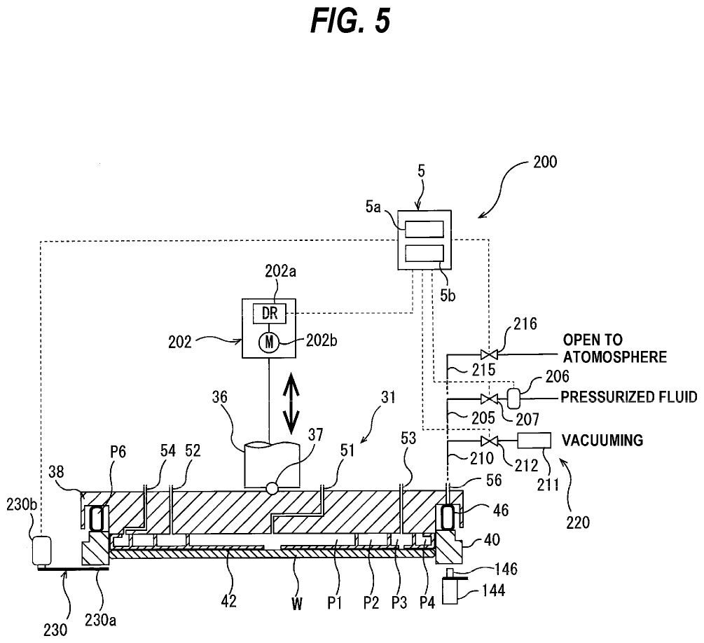

FIG. 5 is a view showing the substrate processing system. As shown in FIG. 5, a substrate processing system 200 includes the top ring 31 (i.e., 31A to 31D) which includes the vertically movable retainer ring 40 and the elastic bag 46 for vertically moving the retainer ring 40, a vacuum forming mechanism 220 connected to the elastic bag 46, and the controller 5 connected to the vacuum forming mechanism 220.

The substrate processing system 200 includes all or some of the components of the substrate processing apparatus shown in FIG. 1. In one embodiment, the substrate processing system 200 may include a controller other than the controller 5 shown in FIG. 1.

The top ring shaft 36 is connected to a vertically moving device 202 for vertically moving the top ring 31 through the top ring shaft 36. One example of the vertically moving device 202 is a servomotor or an air cylinder. The vertically moving device 202 will be described as a servomotor. The servomotor 202 includes a motor driver 202a electrically connected to the controller 5 and a motor body 202b electrically connected to the motor driver 202a. The servomotor 202 is driven in accordance with a command from the controller 5, and the top ring shaft 36 and the top ring 31 move up and down in unison by the servomotor 202.

A pressure line 205 for supplying a pressurized fluid to the interior of the elastic bag 46 (more specifically, the pressure chamber P6) is connected to a fluid channel 56. A pressure adjustment portion 206 for adjusting the pressure of the pressurized fluid supplied to the elastic bag 46, and a pressure valve (on-off valve) 207 disposed downstream of the pressure adjustment portion 206 in the direction of the flow of the pressurized fluid are attached to the pressure line 205. These pressure regulating part 206 and the pressure valve 207 are electrically connected to the controller 5. The controller 5 may control each of the pressure regulating portion 206 and the pressure valve 207.

A vacuum line 210 for forming a vacuum in the interior of the elastic bag 46 (more specifically, the pressure chamber P6) is connected to the fluid channel 56. A vacuum device 211 and a vacuum valve (on-off valve) 212 are attached to the vacuum line 210. The vacuum valve 212 is electrically connected to the controller 5.

When the vacuum device 211 is driven, a vacuum is formed in the elastic bag 46 via the vacuum line 210 and the fluid path 56. The controller 5 operates the vacuum valve 212 to form a vacuum inside the elastic bag 46, or to cut off the formation of the vacuum. The vacuum line 210, the vacuum device 211, and the vacuum valve 212 constitute the vacuum forming mechanism 220.

A vent line 215 is connected to the fluid channel 56 for releasing the interior of the elastic bag 46 (more specifically, the pressure chamber P6) to the atmosphere. A vent valve (on-off valve) 216 is attached to the vent line 215. The vent valve 216 is electrically connected to the controller 5. When the vent valve 216 is opened in a state in which the pressure valve 207 and the vacuum valve 212 are closed, the elastic bag 46 is released to the atmosphere.

The controller 5 includes a memory 5a for storing a program and a processer 5b for performing operations according to the program. The controller 5 comprising a computer operates according to a program electrically stored in the memory 5a. The program includes instructions for the processer 5b to execute an operation to measure a height of the top ring 31 lowering to a top-ring lowered position, for the processer 5b to execute an operation to compare a height of the top ring 31 with a suction start position, and for the vacuum forming mechanism 220 to execute an operation to form a vacuum inside the elastic bag 46 based on the result of a comparison of the height of the top ring 31 with the suction start position.

In other words, the controller 5 performs the steps of having the vertically moving device 202 perform the operation of lowering the top ring 31 to the top-ring lowered position, the step of measuring the height of the lowering top ring 31, the step of comparing the height of the top ring 31 with the suction start position, and the step of having the vacuum forming mechanism 220 perform the operation of forming a vacuum inside the elastic bag 46 based on the result of comparing the height of the top ring 31 with the suction start position.

A program for causing the controller 5 to perform these steps is recorded on a computer-readable recording medium, which is a non-transient tangible object, and provided to the controller 5 via the recording medium. Alternatively, the program may be input to the controller 5 from a communication device (not shown) via a communication network, such as the Internet or a local area network.

The controller 5 can reliably elevate the retainer ring 40 until the lower surface of the retainer ring 40 is positioned at a position higher than the upper surface of the wafer W by performing such a step. As a result, even when the wafer W is released, the wafer W does not contact the retainer ring 40 and damage to the wafer W is prevented.

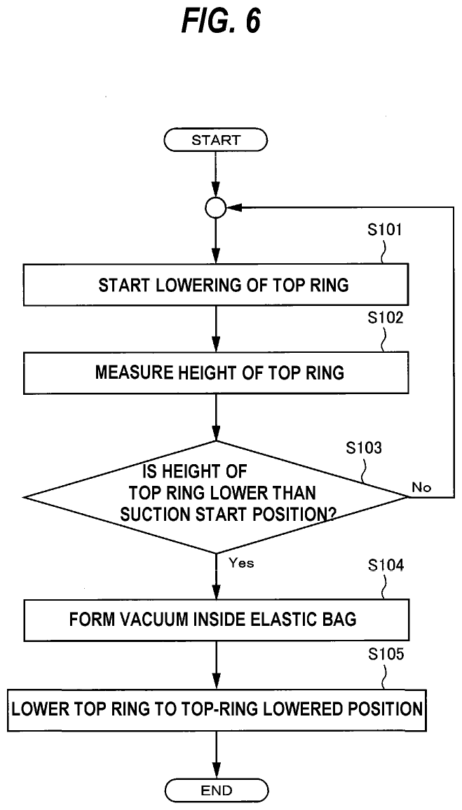

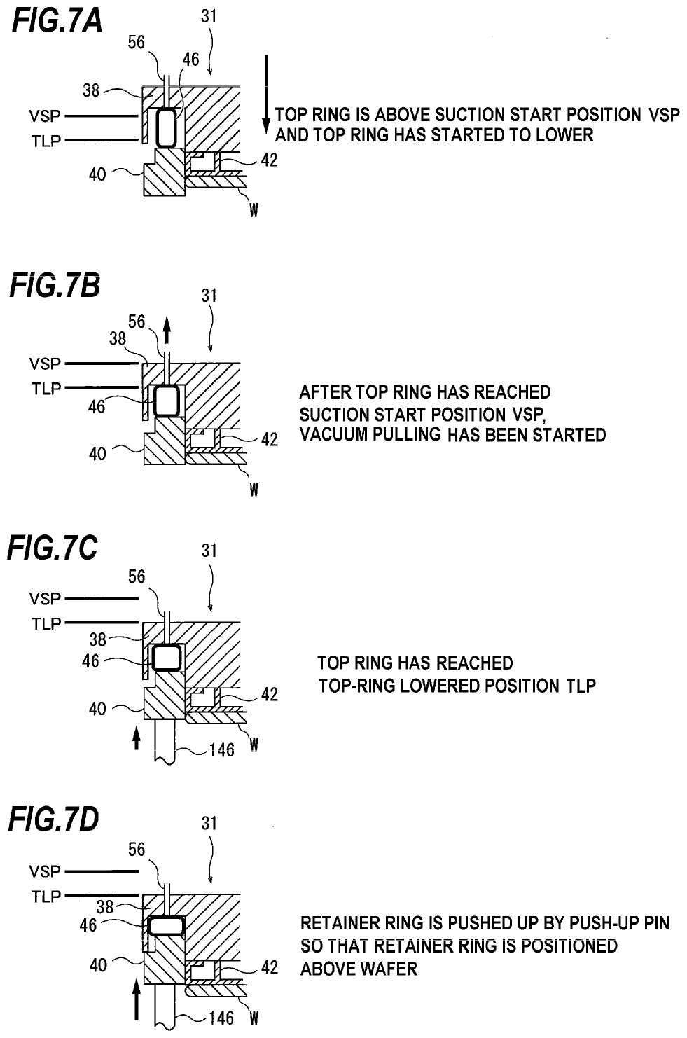

The steps that the controller 5 can perform are described in detail with reference to the drawings. FIG. 6 is a flowchart showing one embodiment of the operation of the controller 5. FIGS. 7A through 7D are views for explaining the operation of the components of the substrate processing system 200. In FIGS. 7A through 7D, a sign VSP indicates the suction start position and a sign TLP indicates the top-ring lowered position.

As shown in FIGS. 6 and 7A, the controller 5 sends a command to the vertically moving device 202 (in this embodiment, the servomotor 202) to start the lowering of the top ring 31 (see step S101). At this time, the top ring 31 is positioned above the suction start position. When the top ring 31 starts to lower, position data indicating the height of the top ring 31 is sent from the servomotor 202 to the controller 5. The controller 5 measures the height of the top ring 31 based on the position data sent from the servomotor 202 (see step S102).

An example of a configuration of a vertically moving device 202 for measuring the height of the top ring 31 will be described. As described above, the vertically moving device 202 is connected to the top ring shaft 36. The vertically moving device 202 detects a displacement of the top ring shaft 36 from a predetermined reference position by a sensor (e.g., an encoder) provided therein. This displacement corresponds to a displacement of the position of the top ring 31.

When the vertically moving device 202 lowers (or elevates) the top ring 31 from the reference position, the vertically moving device 202 detects an amount of displacement of the top ring 31 from the reference position and sends it to the controller 5 as position data. The controller 5 measures the position of the top ring 31, i.e., the height of the top ring 31, based on the position data sent from the vertically moving device 202. In one embodiment, the controller 5 may store in advance in the memory 5a data indicating a correlation between the position data and the height of the top ring 31.

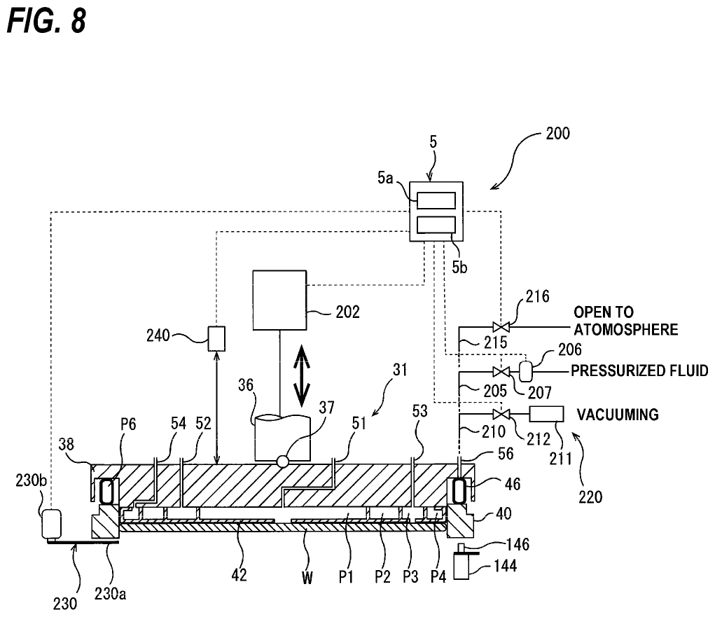

FIG. 8 is a view showing a distance sensor for detecting the height of the top ring 31. In one embodiment, the substrate processing system 200 may include a distance sensor 240 for detecting a distance from the top ring 31. The distance sensor 240 is electrically connected to the controller 5. The distance sensor 240 is disposed above the top ring 31. The distance sensor 240 detects an amount of displacement of the top ring 31 from the reference position, and sends position data indicating this amount of displacement to the controller 5. The controller 5 measures the height of the top ring 31 based on the position data sent from the distance sensor 240.

Returning to FIG. 6, after step S102, the controller 5 compares the height of the top ring 31 with the suction start position, and judges whether the height of the top ring 31 is lower than the suction start position or not (see step S103). If the height of the top ring 31 is not lower than the suction start position, i.e., if the height of the top ring 31 is higher than the suction start position (see “No” in step S103), the controller 5 returns to step S101 and performs a lowering motion of the top ring 31.

When the height of the top ring 31 is lower than the suction start position (see “Yes” in step S03), the controller 5 operates the vacuum forming mechanism 220 to form a vacuum inside the elastic bag 46, as shown in FIG. 7B (see step S104).

The controller 5 is configured to operate the vacuum forming mechanism 220 to form a first vacuum pressure and a second vacuum pressure smaller than the first vacuum pressure in the interior of the elastic bag 46. The first vacuum pressure is closer to atmospheric pressure than the second vacuum pressure. Therefore, when vacuum pulling inside the elastic bag 46 is started, a first vacuum pressure is first formed inside the elastic bag 46, and then a second vacuum pressure is formed.

The first vacuum pressure is a pressure to contract the elastic bag 46 until the retainer ring 40 is elevated, and the second vacuum pressure is a pressure to fully retract the elastic bag 46. Therefore, when the first vacuum pressure is formed inside the elastic bag 46, the elastic bag 46 contracts and the retainer ring 40 is elevated. When the second vacuum pressure is formed inside the elastic bag 46, the elastic bag 46 is completely contracted.

In step S104 of FIG. 6, the controller 5 gradually draws a vacuum inside the elastic bag 46 to form the first vacuum pressure inside the elastic bag 46. As a result, as shown in FIG. 7B the retainer ring 40 is elevated to a height that the retainer ring 40 does not contact a lower surface of the top ring body 38 due to contraction of the elastic bag 46. In FIG. 7B, the retainer ring 40 is elevated until its lower surface becomes the same height as the lower surface of the wafer W. In FIG. 7B, the retainer ring 40 is elevated until its lower surface becomes the same height as the lower surface of the wafer W.

If the second vacuum pressure is formed inside the elastic bag 46 before the top ring 31 is lowered to a top-ring lowered position, the elastic bag 46 may contract completely with a wrinkled part of the elastic bag 46. As a result, the retainer ring 40 may not be elevated normally. Thus, the controller 5 controls the vertically moving device 202 (and/or the vacuum forming mechanism 220) to lower the top ring 31 to the top-ring lowered position before the second vacuum pressure is formed inside the elastic bag 46.

As shown in step S105, the controller 5 lowers the top ring 31 to the top-ring lowered position. As shown in FIG. 7C, when the top ring 31 is lowered to the top-ring lowered position, the lower surface of the retainer ring 40 contacts the push-up pin 146 (see FIG. 5), and the retainer ring 40 is slightly pushed up by the push-up pin 146. At this time, the spring 147 is slightly shrunk by the retainer ring 40. Thereafter, the retainer ring 40 is completely pushed up against the push-up pin 146 by the force applied by the spring 147 (see FIG. 7D). As a result, the retainer ring 40 moves to a position above the wafer W. As a result, the retainer ring 40 moves to a position above the wafer W.

In this manner, the controller 5 opens the vacuum forming mechanism 220, more specifically, the vacuum valve 212, on condition that the height of the top ring 31 is lower than the suction start position. When the vacuum valve 212 is opened, the inside of the elastic bag 46 is evacuated. Therefore, the substrate processing system 200 can prevent air from remaining inside the elastic bag 46, which hinders the normal rise of the retainer ring 40, and the push-up pin 146 causes the retainer ring 40 to move to the wafer W. It can be surely moved to a position above. As a result, the substrate processing system 200 can prevent the wafer W from being damaged due to the contact of the wafer W with the retainer ring 40, and can reliably release the wafer W.

The suction start position is a position for starting a vacuum draw inside the elastic bag 46, and may be set to any value. The suction start position is a constant and variable. In one embodiment, the suction start position may be a position corresponding to the height of the top ring 31 after the retainer ring 40 contacts the push-up pin 146, but before the rise of the retainer ring 40 is terminated.

When the interior of the elastic bag 46 is vacuumed out while a portion of the elastic bag 46 is wrinkled (i.e., deformed so as to be twisted), the elastic bag 46 contracts so as to overlap a portion thereof. Therefore, the retainer ring 40 may not be fully elevated due to the overlap of the elastic bag 46. When the retainer ring 40 is pushed up by the push-up pin 146, the elastic bag 46 is crushed so that its cross-section is elliptical (i.e., spread out to the side). At this timing, the interior of the elastic bag 46 can be vacuumed out without wrinkling a portion of the elastic bag 46.

The timing of vacuuming the interior of the elastic bag 46 is not limited to the above timing. In other embodiments, the suction start position may be a position corresponding to the height of the top ring 31 after the top ring 31 is started to lower, but before the retainer ring 40 comes into contact with the push-up pin 146.

When the push-up pin 146 pushes up the retainer ring 40, the spring 147 (see FIG. 4) that pushes the push-up pin 146 upward exerts a depressive force (in other words, a spring reaction force) on the elastic bag 46. Such a spring reaction force would cause the life of the spring 147 to be shortened. According to the present embodiment, the load acting on the spring 147 can be reduced by forming a vacuum inside the elastic bag 46, and the life of the spring 147 can be prolonged.

Since the retainer ring 40 is in contact with the polishing surface of the polishing pad during polishing of the wafer W, the lower surface of the retainer ring 40 gradually wears out. In one embodiment, the above described program may include a command to cause the processer 5b to perform an operation to measure the amount of wear of the retainer ring 40 and to cause the processer 5b to perform an operation to reflect a distance (value) corresponding to the amount of wear of the retainer ring 40 in the suction start position.

An example of a method of measuring the amount of wear of the retainer ring 40 is as follows. As shown in FIG. 5, the substrate processing system 200 includes a height measurement sensor 230 for measuring the height of the retainer ring 40.

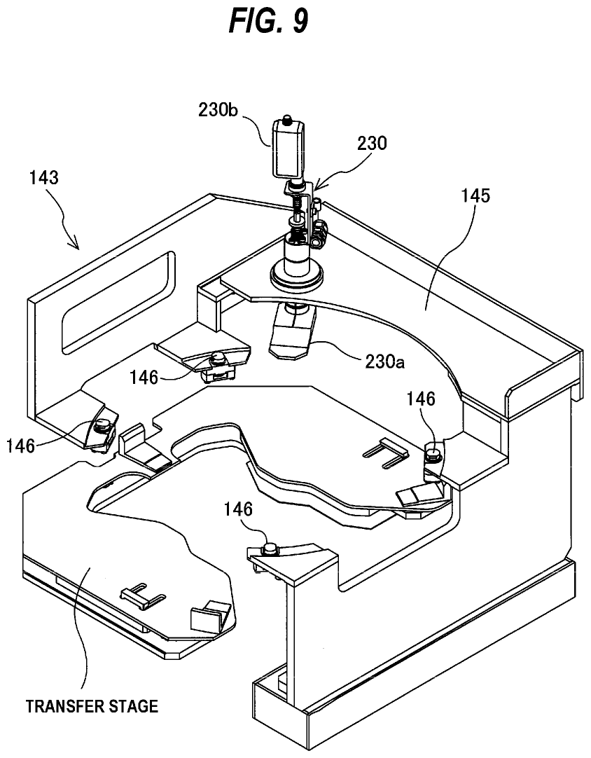

FIG. 9 is a perspective view showing a retainer-ring station 143 including the height measurement sensor 230. The height measurement sensor 230 is disposed on the support base 145 for supporting the pushing mechanism 144, and a relative position of the height measurement sensor 230 and the pushing mechanism 144 is fixed. The height measurement sensor 230 includes a contact portion 230a disposed below the retainer ring 40 and a sensor portion 230b in which the contact portion 230a is fixed. The height measurement sensor 230 is electrically connected to the controller 5. An example of the height measurement sensor 230 may include a displacement sensor.

When the retainer ring 40 is lowered, the lower surface of the retainer ring 40 contacts the contact portion 230a of the height measurement sensor 230. When the retainer ring 40 is further lowered, the contact portion 230a moves downward. The sensor portion 230b detects the movement of the contact portion 230a as a displacement of the retainer ring 40. The controller 5 acquires the height data detected by the height measurement sensor 230 and measures the displacement of the retainer ring 40.

The measured value of the height measurement sensor 230 varies with the amount of wear of the retainer ring 40. Therefore, the controller 5 measures the amount of wear of the retainer ring 40 based on the change in displacement of the retainer ring 40. The controller 5 may measure the amount of wear each time a predetermined number of wafers W is processed.

The controller 5 reflects a distance corresponding to the amount of wear of the retainer ring 40 in the suction start position. For example, the controller 5 is lowered the suction start position by this distance. With such a configuration, the controller 5 can always perform vacuum pulling at a stable timing without being affected by the wear of the retainer ring 40.

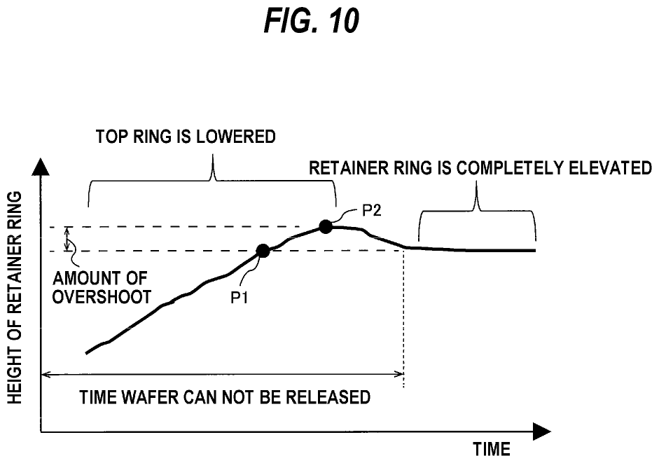

FIG. 10 is a graph showing a temporal change in the height of the retainer ring 40. As shown in FIG. 10, the controller 5 measures the temporal change in the height of the retainer ring 40 by the height measurement sensor 230 until the top ring 31 reaches the top ring descent position. In FIG. 10, the controller 5 measures the amount of overshoot of the temporal change in the height of the retainer ring 40. Where, the “height of the retainer ring 40” refers to the sensor output of the height measurement sensor 230. The sensor output can be expressed by the following equation.

Sensor output=Amount of top ring descent−Amount of elastic bag shrinkage.

The general reasons for this overshoot phenomenon are as follows. When the controller 5 lowers the top ring 31 with the inside of the elastic bag 46 open to the atmosphere, the retainer ring 40 contacts the push-up pin 146 (see P1 of FIG. 10). The retainer ring 40 slightly depresses the push-up pin 146 (see P2 of FIG. 10) due to the air remaining inside the elastic bag 46. Thereafter, the push-up pin 146 pushes up the retainer ring 40 against the push-down force of the retainer ring 40 (elastic bag 46), causing the retainer ring 40 to rise completely.

In this manner, the temporal change in the height of the retainer ring 40 between the time when the retainer ring 40 contacts the push-up pin 146 and the time when the retainer ring 40 begins to rise is referred to as an overshoot phenomenon. When the overshoot phenomenon occurs, the wafer W cannot be released until the retainer ring 40 is completely elevated. As a result, the throughput of the entire process is reduced.

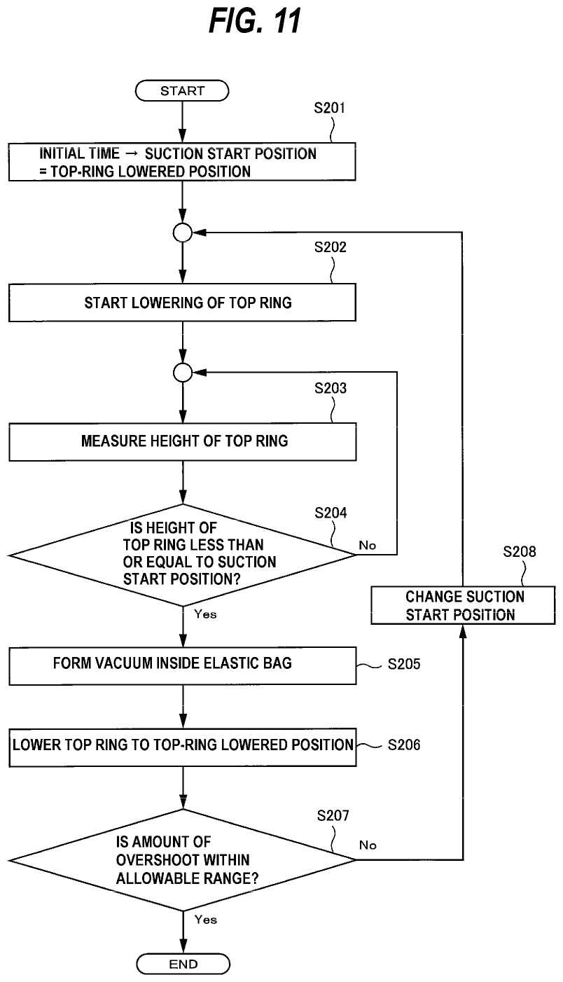

FIG. 11 is a flowchart showing another embodiment of the operation of the controller 5. In the embodiment shown in FIG. 11, the controller 5 is configured to automatically change the suction start position. The controller 5 according to the embodiment shown in FIG. 11 is capable of solving the problem caused by the overshoot phenomenon described above. As shown in step S201 of FIG. 11, when the automatic change of the suction start position is executed, the controller 5 determines the suction start position to the top-ring lowered position (suction start position=top-ring lowered position). In one embodiment, the controller 5 may determine the suction start position to be higher than the top-ring lowered position (suction start position >top-ring lowered position).

As shown in steps S202 and S203 of FIG. 11, the controller 5 starts to lower the top ring 31 and measures the height of the top ring 31. Thereafter, the controller 5 compares the height of the top ring 31 with the suction start position, and judges whether the height of the top ring 31 is less than or equal to the suction start position (see step S204). If the height of the top ring 31 is not less than or equal to the suction start position, i.e., if the height of the top ring 31 is higher than the suction start position (see “No” in step S204), the controller 5 returns to step S202 and executes (continues) a downward motion of the top ring 31.

If the height of the top ring 31 is less than or equal to the suction start position (see “Yes” in step S204), the controller 5 operates the vacuum forming mechanism 220 to form a vacuum inside the elastic bag 46 (see step S205). Thereafter, the controller 5 lowers the top ring 31 to the top-ring lowered position (see step S206). As described above, since the suction start position and the top-ring lowered position are the same in the initial operation of changing the suction start position, the controller 5 omits step S206.

As shown in step S207 of FIG. 11, the controller 5 judges whether the amount of overshoot is within a permissible range, and if the amount of overshoot is not within an allowable range, i.e., if the amount of overshoot is outside the allowable range, the controller 5 changes the suction start position to a position higher than the top-ring lowered position (see step S208).

In one embodiment, the controller 5 may elevate the suction start position by a predetermined value (e.g., 1 mm) from the initial position (in this embodiment, the top-ring lowered position). This value can be set arbitrarily. In other embodiment, the controller 5 may be determined to change the suction start position based on a distance between the most lowered position and the most elevated position of the retainer ring 40.

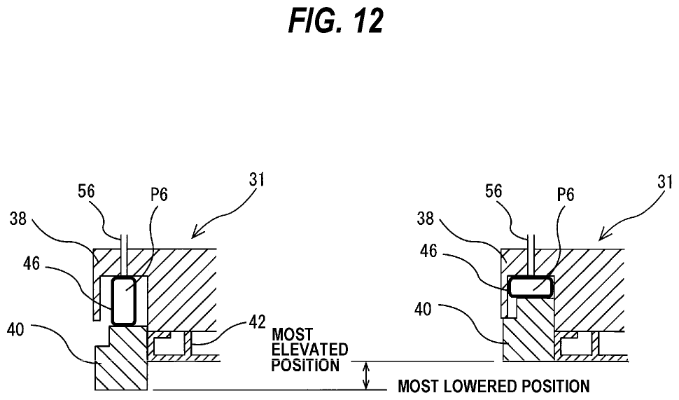

FIG. 12 is a view showing the most lowered position and the most elevated position of the retainer ring 40. As shown in FIG. 12, the most lowered position of the retainer ring 40 is a position on the lower surface of the retainer ring 40 when the retainer ring 40 is most lowered. The most elevated position of the retainer ring 40 is a position on the lower surface of the retainer ring 40 when the retainer ring 40 is most elevated. The controller 5 may divide the distance between the most lowered position and the most elevated position in a predetermined proportion, and reflect the divided value in the change of the suction start position.

After step S208 of FIG. 11, the controller 5 executes steps S202 to S207 again to determine whether or not the amount of overshoot is within the allowable range. If the amount of overshoot is not within an allowable range, the controller 5 repeats the operation of changing the suction start position to a position higher than the top-ring lowered position until the amount of overshoot is within an allowable range.

The controller 5 may initiate vacuum pulling inside the elastic bag 46 by performing such an action, before the push-up pin 146 is pushed down on the retainer ring 40 (elastic bag 46). Therefore, the substrate processing system 200 can reduce the amount of overshoot in the height of the retainer ring 40, and as a result, the wafer W can be promptly released.

If the suction start position is too high, the second vacuum pressure may be formed inside the elastic bag 46 before the top ring 31 reaches the top-ring lowered position. Thus, the controller 5 determines the suction start position to be a height at which the top ring 31 reaches the top-ring lowered position before a second vacuum pressure is formed inside the elastic bag 46.

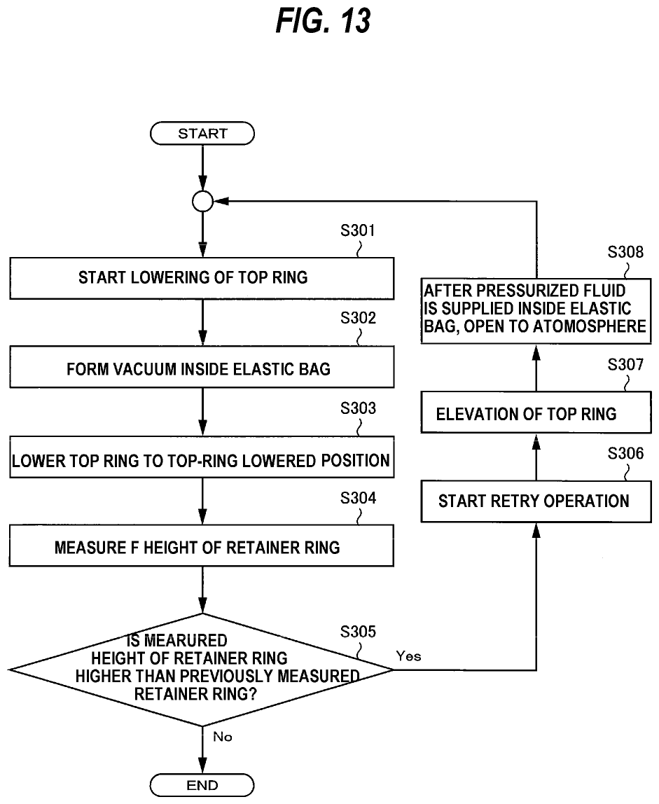

FIG. 13 is a flowchart showing a further embodiment of the operation of the controller 5. In the embodiment shown in FIG. 13, the controller 5 performs an operation to check whether or not the retainer ring 40 has been fully elevated to a predetermined elevated position. As described above, when the interior of the elastic bag 46 is vacuumed out while a portion of the elastic bag 46 is wrinkled (i.e., twisted and deformed), the elastic bag 46 contracts so that a portion of it overlaps. In this case, the retainer ring 40 may not be fully elevated.

Thus, the controller 5 may perform an operation to determine whether or not the retainer ring 40 has been completely elevated. As shown in steps S301 to S303 of FIG. 13, the controller 5 starts to lower the top ring 31, forms a vacuum inside the elastic bag 46, and lowers the top ring 31 to the top-ring lowered position.

Thereafter, the controller 5 measures the height of the retainer ring 40 based on the height data obtained from the height measurement sensor 230 (see step S304), and judges whether the height of the measured retainer ring 40 is higher than the height of the previously measured retainer ring 40 (see step S305). In one embodiment, the height of the retainer ring 40 measured in the past may be averaged over the height of the retainer ring 40 measured multiple times in the past. In other embodiments, the height of the previously measured retainer ring 40 may be the height of the immediately preceding measured retainer ring 40.

If the height of the measured retainer ring 40 is higher than the height of the previously measured retainer ring 40 (see “Yes” in step S305), the controller 5 judges that the retainer ring 40 has not been fully elevated and decides to start a retry operation (see “Yes” in step S306). Thereafter, the controller 5 elevates the top ring 31 to a predetermined position (see step S307), supplies pressurized fluid to the interior of the elastic bag 46, and then opens the interior of the elastic bag 46 to the atmosphere (see step S308). After that, controller 5 executes step S301 again.

If the height of the measured retainer ring 40 is not higher than the height of the previously measured retainer ring 40 (see “No” in step S305), i.e., if the height of the measured retainer ring 40 is lower than the height of the previously measured retainer ring 40, the controller 5 determines that the retainer ring 40 has been completely elevated. After that, the wafer W is released.

Thus, the controller 5 determines whether or not to perform the retry operation based on the height of the retainer ring 40 that has been measured in the past. According to the present embodiment, the controller 5 judges that the retainer ring 40 has been completely elevated, and then the wafer W is released. Therefore, the substrate processing system 200 can more reliably release the wafer W.

In one embodiment, the controller 5 may determine a retry threshold value based on an average of the heights of the retainer ring 40 measured multiple times in the past or the height of the retainer ring 40 measured immediately before. The retry threshold value may be a constant. If the numerical value indicating the height of the measured retainer ring 40 is higher than the retry threshold value, the controller 5 may perform the retry operation.

The program for executing the operation of the controller 5 according to all the above-described embodiments may be stored in the memory 5a. All of the embodiments described above may be combined, wherever possible. The controller 5 may execute the control flow by combining, as far as possible, the embodiments according to FIG. 6, FIG. 11, and FIG. 13.

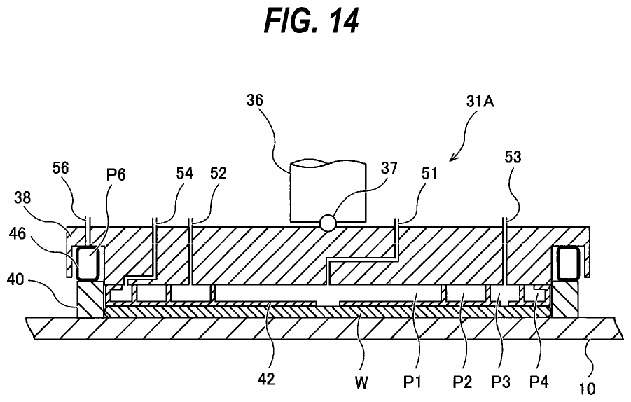

FIG. 14 is a cross-sectional view schematically showing the top ring 31A. The top ring 31A is coupled to a lower end of the top ring shaft 36 via the universal joint 37. This universal joint 37 is a ball joint configured to transmit rotation of the top ring shaft 36 to the top ring 31A while allowing the top ring 31A and the top ring shaft 36 to tile with respect to each other. The top ring 31A includes the top ring body 38 in substantially a disk shape and the retainer ring 40 provided on a lower portion of the top ring body 38. The top ring body 38 is made of a material having high strength and rigidity, such as metal or ceramic. The retainer ring 40 is made of highly rigid resin, ceramic, or the like.

A circular elastic pad 42 that contacts the wafer W is accommodated in the space formed inside the top ring body 38 and the retainer ring 40. The elastic pad 42 is attached to the lower surface of the top ring body 38. Four pressure chambers (airbags) P1, P2, P3, and P4 are provided in the elastic pad 42. Pressurized fluid such as pressurized air is supplied to the pressure chambers P1, P2, P3, and P4 via fluid channels 51, 52, 53, and 54, respectively, or a vacuum is drawn. The central pressure chamber P1 has a circular shape, and the other pressure chambers P2, P3, and P4 have an annular shape. These pressure chambers P1, P2, P3, and P4 are arranged concentrically.

The internal pressures of the pressure chambers P1, P2, P3, and P4 can be changed independently of each other by the pressure adjusting part (not shown), which allows the pressing force on the four regions of the wafer W, i.e., the central part, the inner middle part, the outer middle part, and the peripheral part to be adjusted independently. In addition, the retainer ring 40 can be pressed against the polishing pad 10 with a predetermined pressure by raising and lowering the entire top ring 31A.

The periphery of the wafer W is surrounded by the retainer ring 40 to prevent the wafer W from ejecting from the top ring 31A during polishing. An opening (not shown) is formed in the part of the elastic pad 42 that constitutes the pressure chamber P3, so that the wafer W can be held in the top ring 31A by forming a vacuum in the pressure chamber P3. Moreover, by supplying nitrogen gas, dry air, compressed air, etc. to this pressure chamber P3, the wafer W is released from the top ring 31A.

The elastic bag 46 is placed between the retainer ring 40 and the top ring body 38, and a pressure chamber P6 is formed inside the elastic bag 46. The retainer ring 40 is capable of vertical movement relative to the top ring body 38. Fluid path 56 is connected to the pressure chamber P6, and pressurized fluid such as pressurized air is supplied to the pressure chamber P6 through the fluid path 56. The internal pressure of the pressure chamber P6 can be adjusted by the pressure adjusting part (to be described later). Therefore, the pressing force on the polishing pad 10 of the retainer ring 40 can be adjusted independently of the pressing force on the wafer W. The pressing force on the polishing pad 10 of the retainer ring 40 can be adjusted independently of the pressing force on the wafer W.

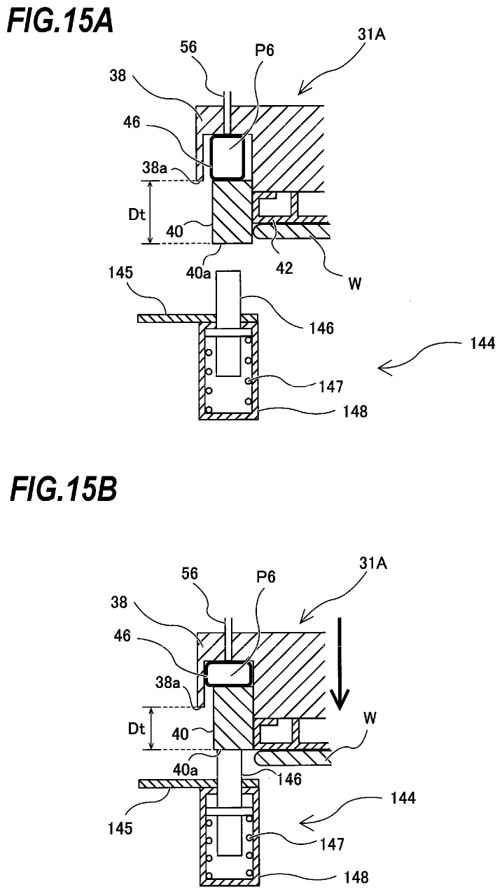

FIG. 15A is a cross-sectional view showing the push-up mechanism 144, and FIG. 15B is a cross-sectional view showing the push-up mechanism 144 when in contact with the retainer ring. The push-up mechanism 144 is provided with the push-up pin 146 in contact with the retainer ring 40, a spring 147 as a push-up mechanism to push the push-up pin 146 upward, and a casing 148 to accommodate the push-up pin 146 and the spring 147. The push-up mechanism 144 is disposed in such a way that the push-up pin 146 is opposed to the lower surface of the retainer ring 40. When the top ring 31A is lowered, the lower surface of the retainer ring 40 contacts the push-up pin 146. As shown in FIG. 15B, the retainer ring 40 is pushed up by the push-up pin 146 and moves to a position above the wafer W. As shown in FIG. 15B, the retainer ring 40 is pushed up by the push-up pin 146 and moves to a position above the wafer W.

As described above, if the retainer ring 40 is not securely attached to the top ring body 38, there is a risk that the retainer ring 40 may not be elevated normally. When the wafer W is released in this state, the wafer W may come into contact with the retainer ring 40 and the wafer W may be damaged.

Thus, the substrate processing system is provided to determine whether or not the retainer ring 40 is securely attached to the top ring body 38. The details of the substrate processing system are described below with reference to the drawings.

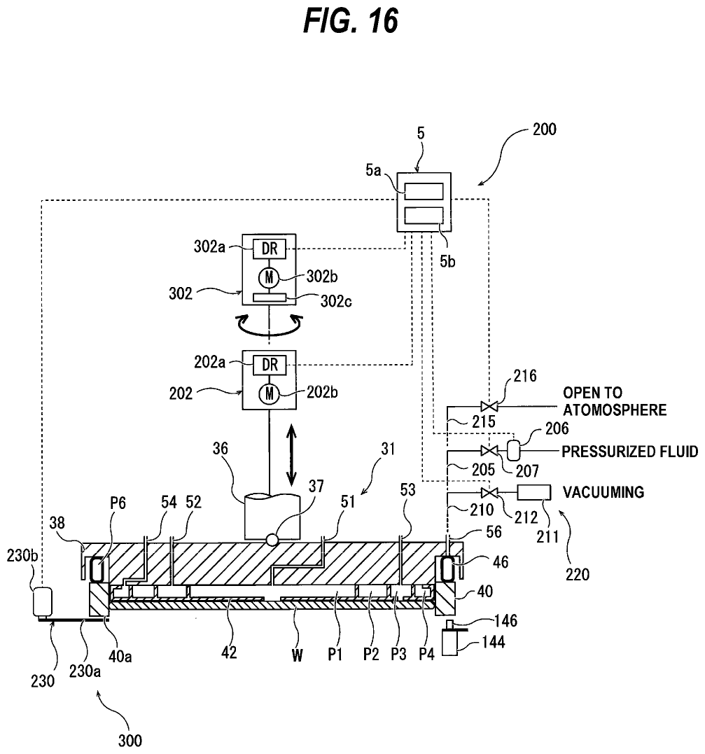

FIG. 16 is a view showing the substrate processing system. As shown in FIG. 16, the substrate processing system 200 is provided with a top ring 31 (i.e., 31A to 31D) including the vertically movable retainer ring 40 and the elastic bag 46 for vertically moving the retainer ring 40, the vacuum forming mechanism 220 connected to the elastic bag 46, and the controller 5 connected to the vacuum forming mechanism 220.

The substrate processing system 200 includes all or some of the components of the substrate processing apparatus shown in FIG. 1. In one embodiment, the substrate processing system 200 may include a controller other than the controller 5 shown in FIG. 1.

The top ring shaft 36 is connected to the vertically moving device 202 for moving the top ring 31 vertically through the top ring shaft 36. An example of the vertically moving device 202 is a servomotor or an air cylinder. The vertically moving device 202 will be described as a servomotor in this specification. The servomotor 202 includes the motor driver 202a electrically connected to the controller 5 and the motor body 202b electrically connected to the motor driver 202a. The servomotor 202 is driven in accordance with a command from the controller 5, and the top ring shaft 36 and the top ring 31 move vertically in unison by the servomotor 202.

The pressure line 205 for supplying a pressurized fluid to the interior of the elastic bag 46 (more specifically, the pressure chamber P6) is connected to the fluid channel 56. The pressure adjustment portion 206 that adjusts the pressure of the pressurized fluid supplied to the elastic bag 46 and the pressure valve (on-off valve) 207 disposed downstream of the pressure adjustment portion 206 in the direction of the flow of the pressurized fluid in the pressure line 205. The pressure adjustment portion 206 and the pressurizing valve 207 are electrically attached to the controller 5. The controller 5 may control each of the pressure adjustment portion 206 and the pressurizing valve 207.

The vacuum line 210 for forming a vacuum in the interior of the elastic bag 46 (more specifically, the pressure chamber P6) is connected to the fluid channel 56. The vacuum device 211 and the vacuum valve (on-off valve) 212 are attached to the vacuum line 210. The vacuum valve 212 is electrically connected to the controller 5.

When the vacuum device 211 is driven, a vacuum is formed in the elastic bag 46 via the vacuum line 210 and the fluid path 56. The controller 5 operates the vacuum valve 212 to form a vacuum inside the elastic bag 46, or to cut off the formation of the vacuum. The vacuum line 210, the vacuum device 211, and the vacuum valve 212 constitute the vacuum forming mechanism 220.

The vent line 215 is connected to the fluid channel 56 for releasing the interior of the elastic bag 46 (more specifically, the pressure chamber P6) to the atmosphere. The vent valve (on-off valve) 216 is attached to the vent line 215. The vent valve 216 is electrically connected to the controller 5. When the open-air valve 216 is opened with the pressure valve 207 and the vacuum valve 212 closed, the elastic bag 46 is released to the atmosphere.

As shown in FIG. 16, the top ring shaft 36 is connected to a rotating device 302 for rotating the top ring 31 via the top ring shaft 36. An example of the rotating device 302 is a servo motor. The rotating device 302 is provided with a motor driver 302a electrically connected to the controller 5, a motor body 302b connected to the motor driver 302a, and a rotary encoder 302c for detecting a rotation angle of the top ring 31. The rotary encoder 302c is a rotation angle detector for detecting the rotation angle of the top ring 31. It should be noted that the rotation angle detector is not limited to a rotary encoder as long as it is provided with a configuration for detecting the rotation angle of the top ring 31.

The rotating device 302 is driven in accordance with a command from the controller 5, and the top ring shaft 36 and the top ring 31 are rotated integrally by the rotating device 302. The controller 5 acquires a rotation angle of the top ring 31 based on the value detected by the rotary encoder 302c. The rotating device 302 rotates the top ring 31 at a predetermined rotation angle in accordance with a command from the controller 5.

The controller 5 includes the memory 5a for storing the program and the processer 5b for performing operations according to the program. The controller 5 comprising a computer operates according to a program electrically stored in the memory 5a. The program causes the processer 5b to perform an operation to compare the height distribution of the retainer ring 40 in the circumferential direction of the retainer ring 40 with a predetermined judgment standard, and causes the processer 5b to perform an operation to judge an abnormality in the attachment of the retainer ring 40 to the top ring body 38 based on the result of comparing the height distribution of the retainer ring 40 with the judgment standard.

In other words, the controller 5 performs a step of having the processer 5b perform an operation to compare a height distribution of the retainer ring 40 in a circumferential direction of the retainer ring 40 with a predetermined judgment standard, and a step of having the processer 5b perform an operation to determine an abnormality in the attachment of the retainer ring 40 to the top ring body 38 based on the result of comparing the height distribution of the retainer ring 40 with the judgment standard.

A program for causing the controller 5 to perform these steps is recorded on a computer-readable recording medium, which is a non-transient tangible object, and provided to the controller 5 via the recording medium. Alternatively, the program may be input to the controller 5 from a communication device (not shown) via a communication network, such as the Internet or a local area network.

An example of a means of obtaining a height distribution of the retainer ring 40 will be described below. As shown in FIG. 16, the substrate processing system 200 is electrically connected to the controller 5 and includes a measuring device 300 for directly or indirectly measuring the height distribution of the retainer ring 40.

In the embodiment shown in FIG. 16, the measuring device 300 includes a height measuring sensor 230 which includes a contact portion 230a that is capable of contacting a lower surface 40a of the retainer ring 40 and a sensor portion 230b that detects a vertical directional movement of the contact portion 230a. An example of the height measurement sensor 230 may include a displacement sensor.

The height measurement sensor 230 is disposed on the support base 145 that supports the push-up mechanism 144 (see FIG. 15), and the relative positions of the height measurement sensor 230 and the push-up mechanism 144 are fixed.

When the top ring 31 is lowered with the retainer ring 40 disposed above the contact portion 230a, the lower surface 40a of the retainer ring 40 contacts the contact portion 230a of the height measurement sensor 230. When the top ring 31 is further lowered, the contact portion 230a moves downward with the retainer ring 40 in contact with it.

The top ring 31 continues to lower until it reaches a predetermined lowered position. The sensor portion 230b detects the vertical movement of the contact portion 230a as a displacement of the retainer ring 40 (i.e., height data of the retainer ring 40), and sends the height data of the retainer ring 40 to the controller 5. The sensor portion 230b detects the vertical movement of the contact portion 230a as a displacement of the retainer ring 40 (i.e., height data of the retainer ring 40), and sends the height data of the retainer ring 40 to the controller 5. The controller 5 obtains a height of the retainer ring 40 based on this height data.

The height of the retainer ring 40 corresponds to a length of the protruding portion of the retainer ring 40 protruding downwardly from the top ring body 38 in this specification. In FIGS. 15A and 15B, the height of the retainer ring 40 corresponds to a distance Dt between the reference surface 38a of the top ring body 38 and the bottom surface 40a of the retainer ring 40.

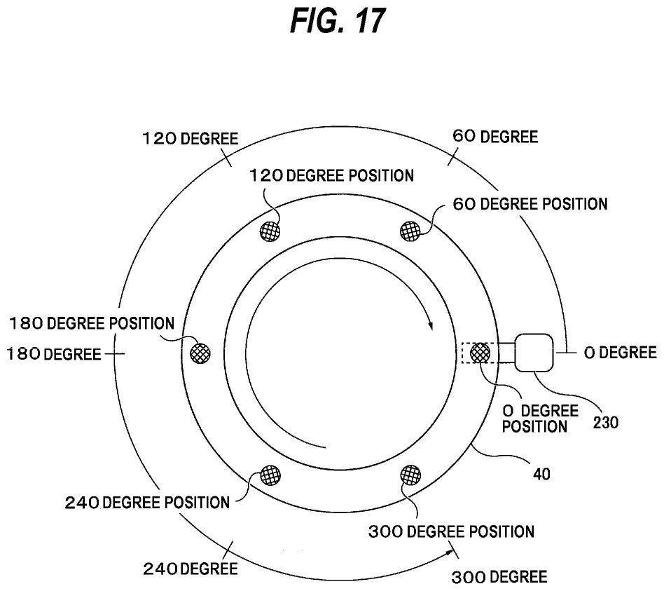

FIG. 17 is a view showing the plurality of rotational angle positions of the retainer ring 40. As shown in FIG. 17, the controller 5 acquires a height distribution of the retainer ring 40 based on the height of the retainer ring 40 at the plurality of rotational angle positions of the retainer ring 40. In the embodiment shown in FIG. 17, the rotational angle position includes a 0-degree position (or 360-degree position), a 60-degree position, a 120-degree position, a 180-degree position, a 240-degree position, and a 300-degree position.

The controller 5 acquires a height of the retainer ring 40 at the six rotational angle positions and acquires a height distribution of the retainer ring 40 based on the height of the retainer ring 40 at these plurality of rotational angle positions. In one embodiment, the controller 5 may acquire a height distribution of the retainer ring 40 at least two rotational angle positions. The operation of the controller 5 to acquire the height distribution of the retainer ring 40 will be described with reference to the drawings below.

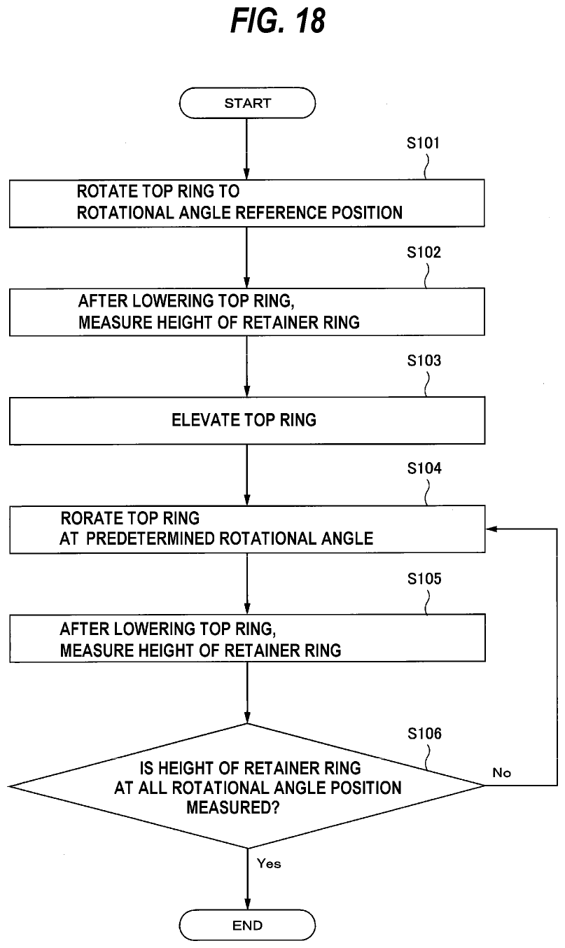

FIG. 18 is a view showing a flowchart for measuring a height of the retainer ring 40 at a plurality of rotational angle positions of the retainer ring 40. First, the controller 5 operates the vertically moving device 202 to raise the top ring 31 to a predetermined height. As shown in step S101 of FIG. 18, the controller 5 rotates the top ring 31 to a predetermined rotational angle reference position (in the embodiment shown in FIG. 17, the 0-degree position) by operating the rotating device 302 based on the current rotational angle position detected by the rotating device 302.

As shown in FIG. 17, a height measurement sensor 230 is disposed below the retainer ring 40 at the 0 degree position. In this state, the controller 5 lowers the top ring 31 to a predetermined lowering position and measures the height of the retainer ring 40 at the 0 degree position (see step S102). After measuring the height of the retainer ring 40, the controller 5 elevates the top ring 31 to a predetermined height (see step S103).

In one embodiment, the controller 5 may operate the vertically moving device 202 to lower the top ring 31 while a vacuum has been formed inside the elastic bag 46. In other embodiment, the controller 5 may lower the top ring 31 by operating the vertically moving device 202 with the interior of the elastic bag 46 open to the atmosphere. In yet another embodiment, the controller 5 may operate the vertically moving device 202 to lower the top ring 31 with pressurized fluid supplied to the interior of the elastic bag 46.

As shown in step S104 of FIG. 18, the controller 5 operates the rotation device 302 to rotate the top ring 31 only at a predetermined rotation angle (the 60 degree in the embodiment shown in FIG. 17) (see the clockwise arrow in FIG. 17). Then, as in step S102, the controller 5 lowers the top ring 31 to a predetermined lowered position and measures the height of the retainer ring 40 at the 60 degree position (see step S105).

The controller 5 repeats the same steps as in step S104 and step S105 until the height of the retainer ring 40 at all rotational angle positions is measured (see “No” in step S106). When the controller 5 measures the height of the retainer ring 40 at all rotation angle positions (see “Yes” in step S106), the operation of measuring the height of the retainer ring 40 is terminated.

Thus, the controller 5 can measure the height of the retainer ring 40 at the plurality of rotational angle positions by executing the flowchart shown in FIG. 18, and obtain a height distribution of the retainer ring 40 in the circumferential direction of the retainer ring 40 based on the measured height of the retainer ring 40.

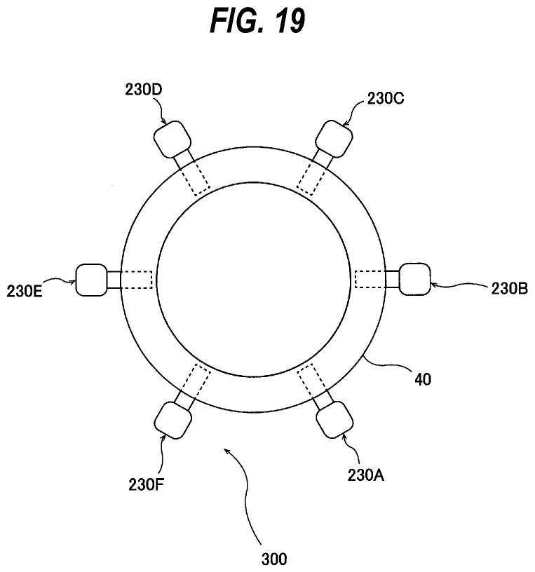

FIG. 19 is a view showing a measuring device 300 with a plurality of height measurement sensors. As shown in FIG. 19, the measuring device 300 may be provided with a plurality of height measurement sensors 230A, 230B, 230C, 230D, 230E, and 230F disposed at equal intervals along the circumferential direction of the retainer ring 40. The number of height measurement sensors 230 is not limited to the embodiment shown in FIG. 19. At least two height measurement sensors 230 may be provided. In one embodiment, the number of height measurement sensors 230 may correspond to the number of rotational angle positions of the retainer ring 40.

In the embodiment shown in FIG. 19, the measuring device 300 includes a plurality of height measurement sensors 230. Therefore, the controller 5 may omit the operation to rotate the top ring 31 at a predetermined rotation angle by operating the rotation device 302 (see step S104 of FIG. 18).

As described above, the controller 5 compares the height distribution of the retainer ring 40 obtained with a predetermined judgment criterion to determine an attachment error of the retainer ring 40 to the top ring body 38. The operation of the controller 5 to determine the attachment error of the retainer ring 40 will be described with reference to the drawings below.

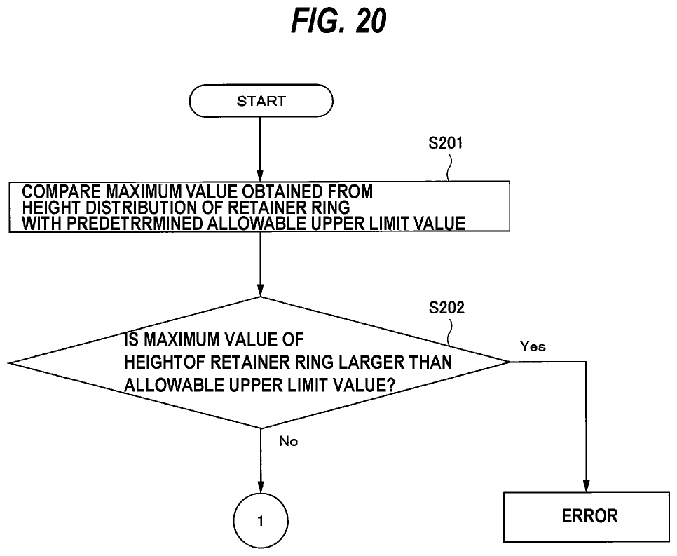

FIGS. 20 to 22 are views a flowchart for judging the attachment error of the retainer ring 40 to the top ring body 38. As shown in step S201 of FIG. 20, the controller 5 causes the processer 5b to perform the operation of comparing a maximum value obtained from the height distribution of the retainer ring 40 with an allowable upper limit value. The allowable upper limit value is a value indicating the allowable upper limit of the height of the retainer ring 40. The above judgement standard includes this allowable upper limit value.

Thereafter, the controller 5 causes the processer 5b to perform an operation to determine the attachment error of the retainer ring 40 to the top ring body 38 on the condition that the above-described maximum value is greater than the allowable upper limit value. More concretely, as shown in step S202 of FIG. 20, the controller 5 judges whether the maximum height of the retainer ring 40 is greater than the permissible upper limit value, and if the maximum height is greater than the allowable upper limit value (see “Yes” of step S202), the controller 5 judges the attachment error of the retainer ring 40 and issues an error signal. An operator removes the retainer ring 40 and the elastic bag 46 based on the error signal emitted by the controller 5, and performs a work of assembling the top ring 31 again.

An example of a cause of the attachment error when the maximum value of the height of the retainer ring 40 is greater than the allowable upper limit value is as follows. As described above, the elastic bag 46 is disposed between the top ring body 38 and the retainer ring 40. Therefore, if the retainer ring 40 is pushed up by the push-up pin 146 (see FIG. 16) while the elastic bag 46 is not properly attached, the retainer ring 40 may be obstructed by the elastic bag 46 and may not be able to be elevated altogether. As a result, the controller 5 judges the attachment error of the retainer ring 40.

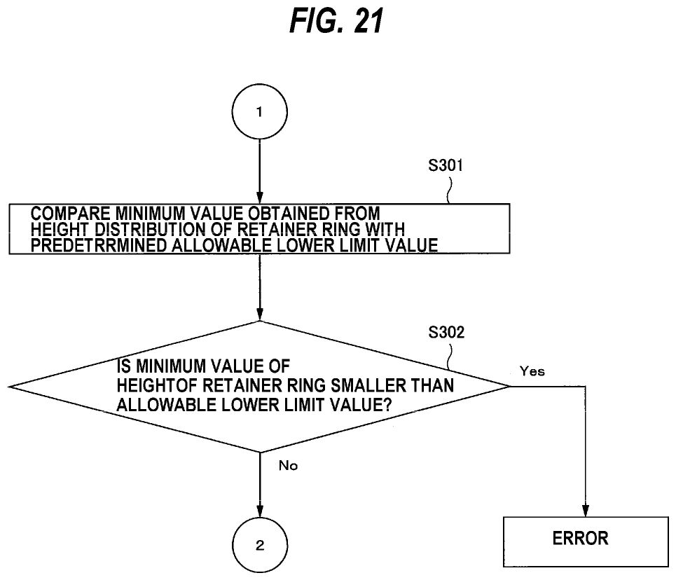

Returning to FIG. 20, when the maximum value of the height of the retainer ring 40 is smaller than the allowable upper limit value (see “No” in step S202), the controller 5 executes the step shown in FIG. 21. As shown in step S301 of FIG. 21, the controller 5 causes the processer 5b to perform an operation to compare the minimum value obtained from the height distribution of the retainer ring 40 with the allowable lower limit value. The allowable lower limit value is a value indicating the lower limit of allowable height of the retainer ring 40. The above judgment standard includes the allowable lower limit value.

The controller 5 causes the processer 5b to perform an operation to determine the attachment error of the retainer ring 40 to the top ring body 38 on the condition that the above-described minimum value is smaller than the allowable minimum value. More specifically, as shown in step S302 of FIG. 21, the controller 5 judges whether the minimum value of the retainer ring 40 is smaller than the allowable lower limit value, and if the minimum value is smaller than the allowable lower limit value (see “Yes” of step S302), the controller 5 judges the attachment error of the retainer ring 40 and emits an error signal.

An example of a cause of the attachment error, when the minimum value of the height of the retainer ring 40 is less than the allowable lower limit value, is as follows. If the retainer ring 40 is pushed up by the push-up pin 146 (see FIG. 16) with the top ring 31 assembled without the elastic bag 46 attached, the retainer ring 40 may be excessively elevated by a distance corresponding to the thickness of the elastic bag 46.

Since the retainer ring 40 is in contact with the polishing surface of the polishing pad 10 during polishing of the wafer W, the lower surface 40a of the retainer ring 40 gradually wears out. Therefore, when the abnormally worn retainer ring 40 is attached, the value indicating the height of the retainer ring 40 becomes abnormally small. As a result, the controller 5 judges the attachment error of the retainer ring 40.

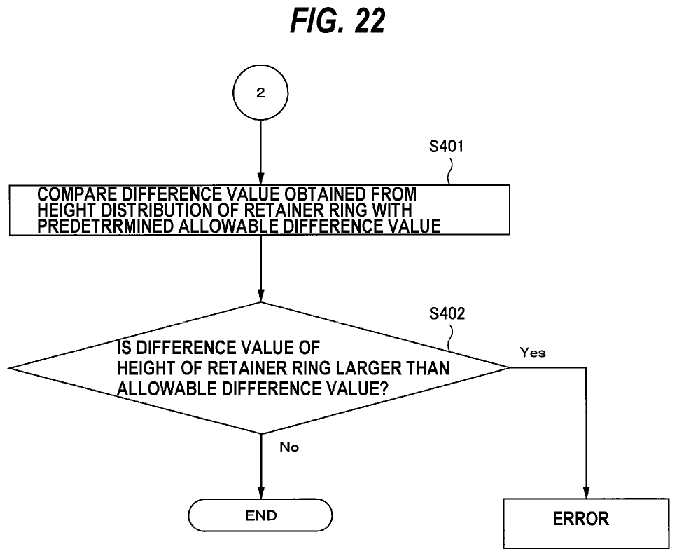

Returning to FIG. 21, if the minimum value is greater than the allowable lower limit value (see “No” of step S302), the controller 5 executes the steps shown in FIG. 22. As shown in step S401 of FIG. 22, the controller 5 calculates a difference value between a maximum value and a minimum value obtained from the height distribution of the retainer ring 40, and causes the processer 5b to perform an operation to compare this difference value with an allowable difference value. The allowable difference value is a value indicating the allowable difference between the allowable upper limit and the allowable lower limit of the height of the retainer ring 40. The above-described judgment standard includes the allowable difference value.

The controller 5 causes the processer 5b to perform an operation to determine the attachment error of the retainer ring 40 to the top ring body 38 on the condition that the above-described difference value is greater than the allowable difference value. More specifically, as shown in step S402 of FIG. 22, when the difference value is greater than the allowable difference value (see “Yes” in step S402), the controller 5 judges the attachment error of the retainer ring 40 and issues an error signal.

An example of a cause of the attachment error in the case where the differential value of the height of the retainer ring 40 is greater than the allowable differential value is as follows. A large differential value of the height of the retainer ring 40 means that the retainer ring 40 is inclined. If a portion of the elastic bag 46 is wrinkled (i.e., twisted and deformed) and the elastic bag 46 is attached, if the retainer ring 40 is pushed up by the push-up pin 146 (see FIG. 16), the portion of the retainer ring 40 cannot be fully elevated due to the overlap of the elastic bag 46. On the other hand, the other parts of the retainer ring 40 are elevated normally. As a result, the controller 5 judges the attachment error of the retainer ring 40.

Returning to FIG. 22, if the difference value is smaller than the allowable difference value (see “No” of step S402), the controller 5 determines that the retainer ring 40 is normally attached to the top ring body 38, and terminates the operation of judging the attachment error.

According to the present embodiment, the controller 5 can determine the attachment error of the retainer ring 40 by comparing the height distribution of the retainer ring 40 with a predetermined judgment standard. Therefore, the substrate processing system 200 may determine whether the retainer ring 40 is securely attached to the top ring body 38.

The controller 5 may automatically perform the above-described operation to determine the attachment error when transporting the wafer W for the first time after replacing the retainer ring 40. With this configuration, the substrate processing apparatus can reduce the risk of producing wafer W while the attachment of the retainer ring 40 is in an abnormal state. In one embodiment, after replacing the retainer ring 40, the operator may manually perform the above-described attachment error determination operation.

In the above-described embodiment, the measuring device 300 is configured to directly measure the height distribution of the retainer ring 40 by the height measuring sensor 230. As described in the following embodiment, the measuring device 300 may be configured to indirectly measure the height distribution of the retainer ring 40.

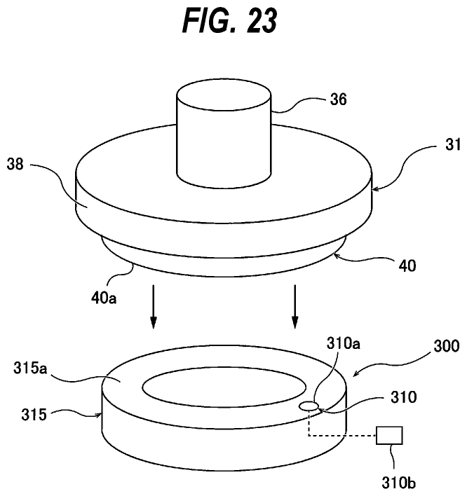

FIG. 23 is a view showing another embodiment of the measuring device 300. Since the configuration of the present embodiment, which is not particularly explained, is the same as the above-described embodiment, the overlapping explanation is omitted. The measuring device 300 includes a pressure measuring sensor 310 for detecting the pressure of the retainer ring 40 moving in a vertical direction. The pressure measurement sensor 310 includes a contact portion 310a that is capable of contacting the lower surface 40a of the retainer ring 40, and a sensor portion 310b that detects a force of the retainer ring 40 acting on the contact portion 310a.

The pressure measurement sensor 310 is supported by the support base 315. The contact portion 310a of the pressure measurement sensor 310 is exposed from the upper surface 315a of the support base 315. When the retainer ring 40 is lowered along with the top ring 31, the lower surface 40a of the retainer ring 40 is pressed against the contact portion 310a of the pressure measuring sensor 310. The sensor portion 310b detects the force of the retainer ring 40 acting on the contact portion 310a and sends the pressure data of the retainer ring 40 to the controller 5. The sensor portion 310b detects the force of the retainer ring 40 acting on the contact portion 310a and sends the pressure data of the retainer ring 40 to the controller 5. The controller 5 obtains the pressure of the retainer ring 40 based on this pressure data.

The controller 5 obtains a pressure distribution of the retainer ring 40 based on the pressure of the retainer ring 40 at the plurality of rotational angle positions (see FIG. 17). More specifically, the controller 5 acquires the pressure distribution of the retainer ring 40 by performing the same operation as steps S101 to S106 shown in FIG. 18.

When the height of the retainer ring 40 at the plural rotation angle positions is different, the force of the retainer ring 40 acting on the contact portion 310a at the plural rotation angle positions is different depending on the height of the retainer ring 40. Thus, since there is a correlation between the pressure of the retainer ring 40 and the height of the retainer ring 40, the pressure distribution of the retainer ring 40 corresponds to the height distribution of the retainer ring 40. Therefore, the measuring device 300 may be described as indirectly measuring the height distribution of the retainer ring 40.

The controller 5 compares the obtained pressure distribution of the retainer ring 40 with a predetermined judgment standard to determine the attachment error of the retainer ring 40. More specifically, after obtaining the pressure distribution of the retainer ring 40, the controller 5 performs the same operations as in the flowcharts shown in FIGS. 20 through 22 to determine the attachment error of the retainer ring 40. The judgment standard includes an allowable upper limit value indicating an allowable upper limit of a pressure corresponding to a height of the retainer ring 40, an allowable lower limit value indicating an allowable lower limit of a pressure corresponding to a height of the retainer ring 40, and an allowable difference value between the allowable upper limit of a pressure corresponding to a height of the retainer ring 40 and the allowable lower limit of a pressure corresponding to a height of the retainer ring 40.

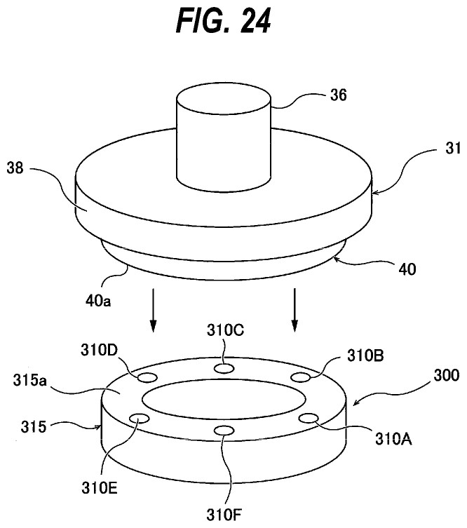

FIG. 24 is a view showing a measuring device 300 with a plurality of pressure measuring sensors 310. As shown in FIG. 24, the measuring device 300 may have a plurality of pressure measuring sensors 310A, 310B, 310C, 310D, 310E, and 310F disposed at equal intervals along the circumferential direction of the support base 315 (i.e., the retainer ring 40). The number of pressure measurement sensors 310 is not limited to the embodiment shown in FIG. 24. At least two pressure measurement sensors 310 may be provided.

In the embodiment shown in FIG. 24, since the measuring device 300 includes a plurality of pressure measuring sensors 310, the controller 5 may omit the operation of rotating the top ring 31 only at a predetermined rotation angle (see step S104 of FIG. 18).

In the above-described embodiment, the controller 5 judges the attachment error of the retainer ring 40 by comparing the predetermined judgment standard stored in the memory 5A with the height distribution (i.e., the pressure distribution) of the retainer ring 40. In one embodiment, the controller 5 may determine the attachment error of the retainer ring 40 based on judgment standard output from a model constructed by machine learning algorithms.

By using the model built with the machine learning algorithms, the judgement standard can be generated automatically and with high accuracy. By using such a judgment standard, the controller 5 can maximize the throughput (i.e., processing capacity per unit of time) of the substrate processing apparatus while maximizing a success rate of wafer W release.

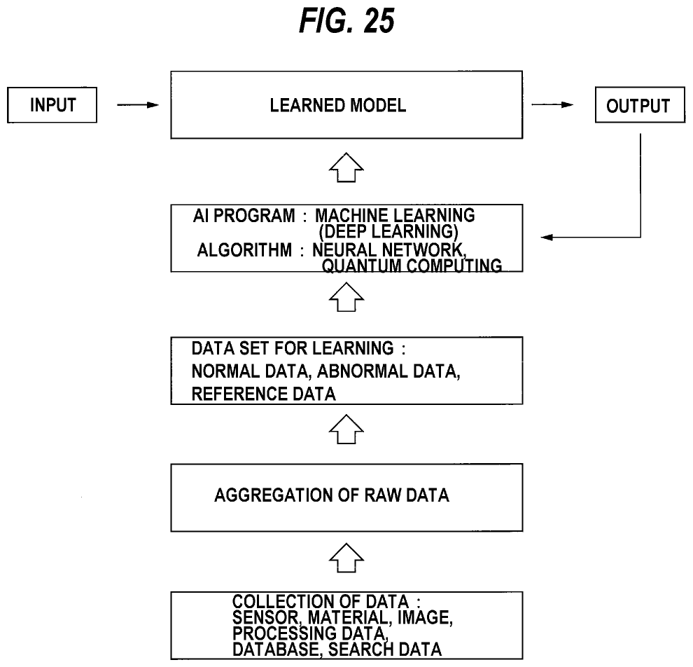

FIG. 25 is a view to illustrate how to construct a learned model. The following is a description of the specific configuration for maximizing the throughput of the substrate processing apparatus while maximizing the success rate of wafer W release.

The controller 5 is configured to learn the judgement standard including various elements and generate the optimal judgement standard using machine learning algorithms such as deep learning. When building a trained model, data are collected and created a collection of raw data (see FIG. 25).

The collection of data is extensive. The data to be collected is not limited to physical quantities (i.e., height of the retainer ring 40, pressure of the retainer ring 40) measured by the measuring device 300. For example, the data may include various elements such as measurements of various sensors disposed in the substrate processing apparatus (e.g., measurement value of the vertically moving device 202, measurement value of the rotating device 302), materials of each component disposed in the substrate processing apparatus (e.g., features (e.g., type, size, etc.) of the elastic bag 46, features (e.g., type, size, etc.) of the retainer ring 40), parameters entered into the substrate processing apparatus by the operator, etc.

Next, from the set of raw data, a training dataset needed to build (and update) the trained model is created. If the judgment standard is set excessively strictly, the success rate of wafer W release will increase, but the rate of error judgment by the controller 5 will also increase. As a result, the throughput of the substrate processing apparatus is reduced. Conversely, if the judgment standard is set excessively gently, the rate of error judgment by the controller 5 will decrease, but the success rate of wafer W release will also decrease. As a result, the throughput of the substrate processing apparatus is reduced.

Therefore, in this embodiment, the model is constructed using the data set consisting of the combination of the actual judgment standard, the success rate of the release of the wafer W based on the actual judgment standard, and the throughput of the substrate processing apparatus based on the actual judgment standard.

In one embodiment, in constructing the model, an explanatory variable of the learning data can be used as a judgment standard, and the objective variable of the learning data can be given as a numerical value representing a success rate of release of the wafer W and a good or bad throughput of the substrate processing apparatus.

As shown in FIG. 25, machine learning using neural networks or quantum computing is performed to construct a learned model. For machine learning using neural networks or quantum computing, deep learning methods (deep learning methods) are preferred. Deep learning methods are learning methods based on neural networks with multiple layers of hidden layers (also known as middle layers).

The memory 5a stores a model constructed by a machine learning algorithm, and the processer 5b inputs at least the polishing conditions of the wafer W and the type of retainer ring 40 used under these polishing conditions into the model, and executes the operation to output the judgment standard for judging the attachment error of the retainer ring 40 from the model. The judgement standard output from the model may be reflected in the training dataset for updating the learned model.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments. Therefore, the present invention is not intended to be limited to the embodiments described herein but is to be accorded the widest scope as defined by limitation of the claims and equivalents.

What is claimed is:

1. A substrate processing system comprising:
a top ring comprising a vertically movable retainer ring and an elastic bag configured to vertically move the retainer ring;
a vacuum forming mechanism coupled to the elastic bag; and
a controller connected to the vacuum forming mechanism,
wherein the controller comprises a memory storing a program and a processer executing operations according to the program, and
wherein the program causes the processer to measure a height of the top ring lowering to a top-ring lowered position, the processer to compare the height of the top ring with a suction start position, and the vacuum forming mechanism to form a vacuum inside the elastic bag based on a result of comparing the height of the top ring with the suction start position.

2. The substrate processing system according to claim 1, wherein the program causes the vacuum forming mechanism to form the vacuum inside the elastic bag on a condition that the height of the top ring is lower than the suction start position.

3. The substrate processing system according to claim 1, wherein the program causes the processer to measure a temporal change in the height of the retainer ring until the top ring reaches the top-ring lowered position, the processer to compare whether or not an amount of overshoot of the temporal change is within a predetermined allowable range, and the processer to change the suction start position to a position higher than the top-ring lowered position on a condition that the amount of overshoot is not within the predetermined allowable range.

4. The substrate processing system according to claim 3, wherein the program causes the processer to repeat an operation of changing the suction start position to a position higher than the top-ring lowered position until the amount of overshoot is within the allowable range.

5. The substrate processing system according to claim 3, wherein the program causes the processer to change the suction start position based on a distance between a most lowered position and a most elevated position of the retainer ring.

6. The substrate processing system according to claim 1, wherein the program causes the processer to measure a wear amount of the retainer ring, and the processer to reflect a distance corresponding to the wear amount of the retainer ring to the suction start position.

7. The substrate processing apparatus according to claim 1, wherein the program causes the processer to measure the height of the retainer ring after the top ring is lowered to the top-ring lowered position, the processer to judge whether or not the height of the measured retainer ring is higher than the height of a previously measured retainer ring, and the processer to determine a start of a retry operation to lower the top ring again on a condition that the height of the measured retainer ring is higher than the height of the previously measured retainer ring.

8. A non-transitory computer-readable storage medium storing a program, the program for causing a computer to perform steps comprising:
lowering a top ring to a top-ring lowered position by a top-ring vertically moving device, the top ring comprising a vertically movable retainer ring and an elastic bag configured to vertically move the retainer ring;
measuring a height of the top ring lowering;
comparing the height of the top ring with a suction start position; and
forming a vacuum inside the elastic bag by a vacuum forming mechanism coupled to the elastic bag based on a result of comparing the height of the top ring with the suction start position.

9. A substrate processing system comprising:
a top ring comprising a retainer ring and a top ring body attached to the retainer ring;
a measuring device configured to directly or indirectly measure a height distribution of the retainer ring; and
a controller comprising a memory storing a program and a processer executing operations according to the program, the controller being connected to the measuring device,
wherein the program causes the processer to compare a height distribution of the retainer ring with a predetermined judgement standard, and the processer to judge an attachment error of the retainer ring to the top ring body based on a result of comparison between the height distribution of the retainer ring and the judgment standard.

10. The substrate processing system according to claim 9, wherein the judgement standard comprises an allowable upper limit value indicating an allowable upper limit of the height of the retainer ring, and
wherein the program causes the processer to compare a maximum value obtained from the height distribution of the retainer ring with the allowable upper limit value, and the processer to judge the attachment error of the retainer ring to the top ring body on a condition that the maximum value is larger than the allowable upper limit value.

11. The substrate processing system according to claim 9, wherein the judgement standard comprises an allowable lower limit value indicating an allowable lower limit of the height of the retainer ring, and
wherein the program causes the processer to compare a minimum value obtained from the height distribution of the retainer ring with the allowable lower limit value, and the processer to judge the attachment error of the retainer ring to the top ring body on a condition that the minimum value is smaller than the allowable lower limit value.

12. The substrate processing system according to claim 9, wherein the judgement standard comprises an allowable difference value between an allowable upper limit and an allowable lower limit of the retainer ring, and
wherein the program causes the processer to compare a difference value between a maximum value and a minimum value obtained a height distribution of the retainer ring, and the processer to judge the attachment error of the retainer ring to the top ring body on a condition that the difference value is larger than the allowable difference limit value.

13. The substrate processing system according to claim 9, wherein the measuring device comprises a height measurement sensor configured to detect a vertical direction movement of the retainer ring, and
wherein the controller causes the processer to obtain a height distribution of the retainer ring based on height data in a plurality of rotational angle positions of the retainer ring detected by the height measurement sensor.

14. The substrate processing system according to claim 9, wherein the measuring device comprises a pressure measurement sensor configured to detect a pressure of the retainer ring moving vertically,
wherein the controller causes the processer to obtain a pressure distribution of the retainer ring corresponding to the height distribution of the retainer ring based on pressure data in a plurality of rotational angle positions of the retainer ring detected by the pressure measurement sensor.

15. The substrate processing system according to claim 9, wherein the memory stores a model constructed by a machine learning algorithm, and
wherein the processer inputs at least a polishing condition of a substrate and a type of retainer ring to be used into the model, and executes operations to output the judgement standard from the model.

16. The substrate processing system according to claim 15, wherein the model is constructed based on a data set comprising a combination of actual judgement standard, a successful rate of substrate release based on actual judgement standard, and a throughput of a substrate processing apparatus.

17. A non-transitory computer-readable storage medium storing a program, the program for causing a computer to perform steps comprising:
comparing a height distribution of a retainer ring attached to a top ring body and a predetermined judgement standard; and
judging an attachment error of the retainer ring to the top ring body based on a result of comparison between the height distribution of the retainer ring and the judgment standard.
